(19) United States
(12) Patent Application Publication
(10) Pub. No.: US 2025/0098267 A1
(43) Pub. Date: Mar. 20, 2025

(54) BACKSIDE BI-DIRECTIONAL INTERCONNECT

(71) Applicant: QUALCOMM Incorporated, San Diego, CA (US)

(72) Inventors: Yan SUN, San Diego, CA (US); Deepak SHARMA, San Diego, CA (US); Shreesh NARASIMHA, Charlotte, NC (US)

(21) Appl. No.: 18/469,473

(22) Filed: Sep. 18, 2023

(51) Int. Cl. H01L 29/417; H01L 21/8234; H01L 23/528; H01L 27/088; H01L 29/06; H01L 29/423; H01L 29/775; H01L 29/786

(52) U.S. Cl. CPC H10D 64/256; H01L 23/5286; H10D 30/43; H10D 30/6735; H10D 30/6757; H10D 62/121; H10D 84/0149; H10D 84/038; H10D 84/83

(57) ABSTRACT

Disclosed are techniques for a semiconductor structure. In an aspect, a semiconductor structure includes a gate stack including a first gate structure and a second gate structure offset in a first direction. The semiconductor structure includes a first source/drain (S/D) structure adjacent the first gate structure, a second S/D structure adjacent the second gate structure, a first backside conductive structure in contact with the first S/D structure, and a second backside conductive structure in contact with the second S/D structure. The semiconductor structure includes a third backside conductive structure disposed in a back portion of the semiconductor structure opposing a front portion of the semiconductor structure, extending along a second direction, and in contact with the first backside conductive structure and the second backside conductive structure.

### TECHNICAL FIELD

The present disclosure generally relates to a semiconductor structure of an integrated circuit device, and more particularly, to a semiconductor structure with backside bi-directional interconnects.

### BACKGROUND

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components from a front side of the IC device. As the sizes of the IC devices and the sizes of the components formed thereon become smaller, and the available area for forming the contacts and interconnects also become smaller. As such, the routing complexity and/or parasitic resistance and capacitance of the contacts and interconnects may increase and thus the manufacturing cost or the performance of the IC device may be negatively impacted.

Accordingly, in order to further reduce the routing complexity and/or reduce parasitic resistance and capacitance, there is a need for improved structures or manufacturing methods of the contacts and interconnects.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a semiconductor structure includes a gate stack extending along a first direction in a front portion of the semiconductor structure, the gate stack including a first gate structure and a second gate structure offset from each other in the first direction; a first source/drain (S/D) structure adjacent the first gate structure; a second S/D structure adjacent the second gate structure, the second S/D structure being offset from the first S/D structure in a second direction; a first backside conductive structure in contact with the first S/D structure and disposed at least partially in a back portion of the semiconductor structure opposing the front portion; a second backside conductive structure in contact with the second S/D structure and disposed at least partially in the back portion of the semiconductor structure; and a third backside conductive structure disposed in the back portion of the semiconductor structure, the third backside conductive structure extending along the second direction and in contact with the first backside conductive structure and the second backside conductive structure.

In an aspect, a method of manufacturing a semiconductor structure includes forming a gate stack extending along a first direction in a front portion of the semiconductor structure, the gate stack including a first gate structure and a second gate structure, the second gate structure being offset from the first gate structure in the first direction, a first S/D structure being disposed adjacent the first gate structure, a second S/D structure being disposed adjacent the second gate structure, and the first S/D structure and the second S/D structure being offset from each other in a second direction; forming a first backside conductive structure in contact with the first S/D structure and disposed at least partially in a back portion of the semiconductor structure opposing the front portion; forming a second backside conductive structure in contact with the second S/D structure and disposed at least partially in the back portion of the semiconductor structure; and forming a third backside conductive structure disposed in the back portion of the semiconductor structure, the third backside conductive structure extending along the second direction and in contact with the first backside conductive structure and the second backside conductive structure.

In an aspect, an electronic device includes an integrated circuit device including a semiconductor structure, and the semiconductor structure comprising: a gate stack extending along a first direction in a front portion of the semiconductor structure, the gate stack including a first gate structure and a second gate structure offset from each other in the first direction; a first source/drain (S/D) structure adjacent the first gate structure; a second S/D structure adjacent the second gate structure, the second S/D structure being offset from the first S/D structure in a second direction; a first backside conductive structure in contact with the first S/D structure and disposed at least partially in a back portion of the semiconductor structure opposing the front portion; a second backside conductive structure in contact with the second S/D structure and disposed at least partially in the back portion of the semiconductor structure; and a third backside conductive structure disposed in the back portion of the semiconductor structure, the third backside conductive structure extending along the second direction and in contact with the first backside conductive structure and the second backside conductive structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1 is a top view of a portion of a semiconductor structure of an integrated circuit (IC) device, according to aspects of the disclosure.

FIGS. 2A and 2B are top views of a portion of a semiconductor structure of an IC device, with emphasis of elements at different vertical regions thereof, according to aspects of the disclosure.

FIGS. 3A and 3B are top views of a portion of a semiconductor structure of an IC device, with emphasis of elements at different vertical regions thereof, according to aspects of the disclosure.

FIGS. 3C-3E are cross-sectional views of a portion of the semiconductor structure of FIGS. 3A and 3B, according to aspects of the disclosure.

FIGS. 4A and 4B illustrate a manufacturing process for manufacturing a semiconductor structure, according to aspects of the disclosure.

FIG. 5A is a top view of a portion of a semiconductor structure of an IC device, according to aspects of the disclosure.

FIG. 5B is a cross-sectional view of a portion of the semiconductor structure of FIG. 5A, according to aspects of the disclosure.

FIGS. 6A and 6B illustrate a manufacturing process for manufacturing a semiconductor structure, according to aspects of the disclosure.

FIGS. 7A-7K illustrate structures at various stages of manufacturing a semiconductor structure of FIGS. 3A-3E, according to aspects of the disclosure.

FIGS. 8A-8B illustrate structures at various stages of manufacturing a semiconductor structure of FIGS. 5A-5B, according to aspects of the disclosure.

FIG. 9A is a top view of a portion of a semiconductor structure of an IC device, according to aspects of the disclosure.

FIGS. 9B and 9C are cross-sectional views of a portion of the semiconductor structure of FIG. 9A, according to aspects of the disclosure.

FIG. 10 is a cross-sectional view of a portion of the semiconductor structure, according to aspects of the disclosure.

FIGS. 11A and 11B illustrate a manufacturing process for manufacturing a semiconductor structure, according to aspects of the disclosure.

FIG. 12 is a cross-sectional view of a portion of the semiconductor structure, according to aspects of the disclosure.

FIGS. 13A and 13B illustrate a manufacturing process for manufacturing a semiconductor structure, according to aspects of the disclosure.

FIGS. 14A-14E illustrate structures at various stages of manufacturing a semiconductor structure of FIGS. 9A-9C, according to aspects of the disclosure.

FIGS. 15A-15D illustrate structures at various stages of manufacturing a semiconductor structure of FIG. 10, according to aspects of the disclosure.

FIGS. 16A-16C illustrate structures at various stages of manufacturing a semiconductor structure of FIG. 12, according to aspects of the disclosure.

FIG. 17 illustrates a method for manufacturing a semiconductor structure, according to aspects of the disclosure.

FIG. 18 illustrates a mobile device example, according to aspects of the disclosure.

FIG. 19 illustrates various electronic devices that may be integrated with IC devices, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to a semiconductor structure of an integrated circuit device and a manufacturing method of making the semiconductor structure. Some aspects more specifically relate to a semiconductor structure with backside bi-directional interconnects.

Particular aspects of the subject matter described in this disclosure can be implemented to realize one or more of the following potential advantages. In some examples, by forming the backside conductive structures extending along two different directions, the backside conductive structures may form interconnections at the back portion of the semiconductor structure of an integrated circuit device, which may provide additional routing capability or capacity for manufacturing the integrated circuit device.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

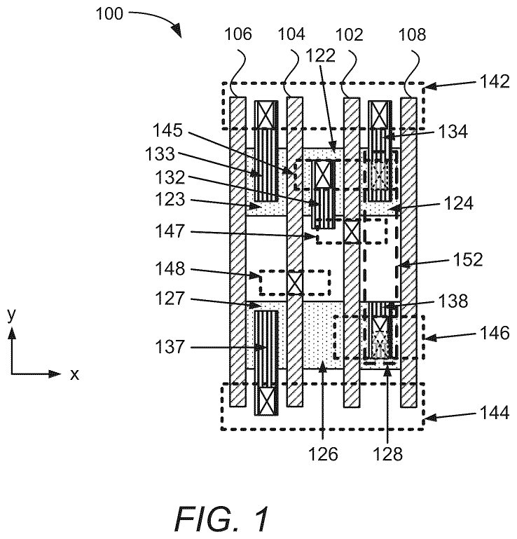

FIG. 1 is a top view of a portion of a semiconductor structure 100 of an integrated circuit (IC) device, according to aspects of the disclosure. In some aspects, FIG. 1 merely shows some elements of the semiconductor structure 100 for illustration purposes, and other elements above and/or below the elements shown in FIG. 1 may be disposed in the IC device but not shown in FIG. 1.

As shown in FIG. 1, the semiconductor structure 100 includes gate stacks 102, 104, 106, and 108 extending along a first direction (e.g., the y direction), a source/drain (S/D) structure 122 between the gate stacks 102 and 104, an S/D structure 123 between the gate stacks 104 and 106, an S/D structure 124 between the gate stacks 102 and 108, an S/D structure 126 between the gate stacks 102 and 104, an S/D structure 127 between the gate stacks 104 and 106, and an S/D structure 128 between the gate stacks 102 and 108. The S/D structure 122 and the S/D structure 126 are disposed apart from each other in the first direction, the S/D structure 123 and the S/D structure 127 are disposed apart from each other in the first direction, and the S/D structure 124 and the S/D structure 128 are disposed apart from each other in the first direction.

A portion of the gate stack 102 adjacent the S/D structure 122 and the S/D structure 124 may be configured as a first gate structure, and a first channel structure may be formed through the first gate structure in a second direction (e.g., the x direction). The S/D structure 122 and the S/D structure 124 may be electrically coupled to the first channel structure. A portion of the gate stack 102 adjacent the S/D structure 126 and the S/D structure 128 may be configured as a second gate structure, and a second channel structure may be formed through the second gate structure in the second direction. The S/D structure 126 and the S/D structure 128 may be electrically coupled to the second channel structure.

A portion of the gate stack 104 adjacent the S/D structure 122 and the S/D structure 123 may be configured as a third gate structure, and a third channel structure may be formed through the third gate structure in the second direction. The S/D structure 122 and the S/D structure 123 may be electrically coupled to the third channel structure. Also, a portion of the gate stack 104 adjacent the S/D structure 126 and the S/D structure 127 may be configured as a fourth gate structure, and a fourth channel structure may be formed through the fourth gate structure in the second direction. The S/D structure 126 and the S/D structure 127 may be electrically coupled to the fourth channel structure.

In some aspects, the S/D structures 122, 123, and 124 may have a first doping type, and the S/D structures 126, 127, and 128 may have a second doping type different from the first doping type.

In some aspects, the first gate structure, the first channel structure, the S/D structure 122, and the S/D structure 124 may be configured as a first transistor of a first type; and the second gate structure, the second channel structure, the S/D structure 126, and the S/D structure 128 may be configured as a second transistor of a second type. In some aspects, the third gate structure, the third channel structure, the S/D structure 122, and the S/D structure 123 may be configured as a third transistor of the first type; and the fourth gate structure, the fourth channel structure, the S/D structure 126, and the S/D structure 127 may be configured as a fourth transistor of the second type. In some aspect, the gate stacks 106 and 108 may be configured as dummy gates that are to be biased to electrically separating the S/D structures 123, 124, 127, and 128 from neighboring S/D structures (not shown).

As shown in FIG. 1, the semiconductor structure 100 includes a contact 132 electrically coupled to the S/D structure 122, a contact 133 electrically coupled to the S/D structure 123, a contact 134 electrically coupled to the S/D structure 124, a contact 137 electrically coupled to the S/D structure 127, and a contact 138 electrically coupled to the S/D structure 128. The semiconductor structure 100 includes a conductive structure 142 electrically coupled to the contacts 133 and 134 through corresponding via structures (not labeled, depicted as solid-line boxes with cross marks). The semiconductor structure 100 includes a conductive structure 144 electrically coupled to the contact 137 through a via structure (not labeled, depicted as a solid-line box with a cross mark). Moreover, the semiconductor structure 100 includes conductive structures 145, 146, 147, and 148 electrically coupled to the contacts 132 and 138 and gate stacks 102 and 104, respectively through corresponding via structures (not labeled, depicted as solid-line boxes with cross marks). Also, the semiconductor structure 100 includes a conductive structure 152 electrically coupled to the conductive structures 145 and 146 through corresponding via structures (not labeled, depicted as dotted-line boxes with cross marks).

In some aspects, the conductive structure 142 may be a first power line configured to carry a first power voltage (e.g., VDD), and the conductive structure 144 may be a second power line configured to carry a second power voltage (e.g., VSS or ground). In some aspects, the conductive structure 147 may be a signal line configured to carry a first gate voltage for controlling the first gate structure of the first transistor and the second gate structure of the second transistor. In some aspects, the conductive structure 148 may be a signal line configured to carry a second gate voltage for controlling the third gate structure of the third transistor and the fourth gate structure of the fourth transistor. In some aspects, the conductive structure 152 may be a signal line configured to carry an output voltage at the S/D structure 122 of the first transistor and the S/D structure 128 of the second transistor. In some aspects, the portion of the semiconductor structure 100 shown in FIG. 1 forms a NAND gate and may be used as a standard cell of a NAND gate for manufacturing the IC device.

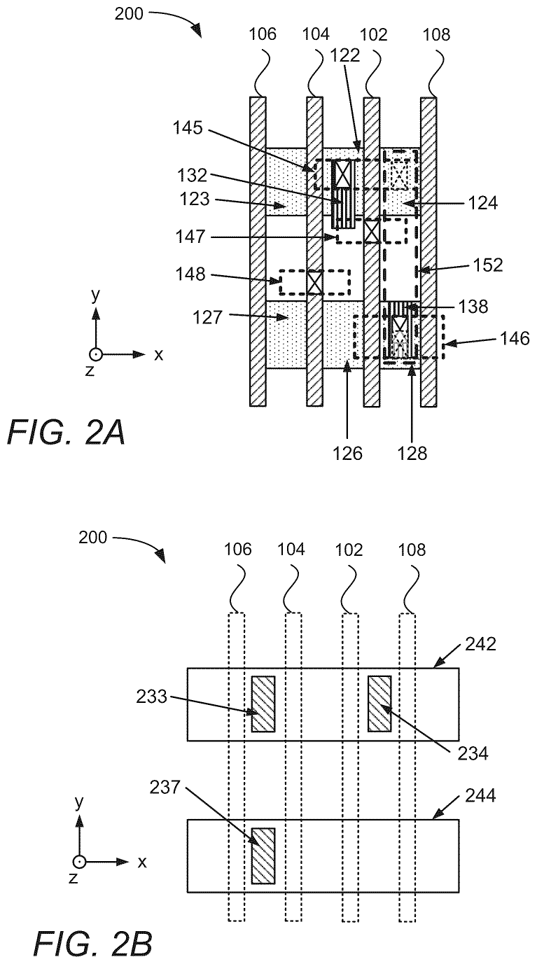

FIGS. 2A and 2B are top views of a portion of a semiconductor structure 200 of an IC device, with emphasis of elements at different vertical regions thereof, according to aspects of the disclosure. In particular, the elements shown in FIG. 2A show the elements that may be above the elements shown in FIG. 2B in a vertical direction (e.g., the z direction corresponding to a direction leaving the plane of the drawing sheet). In some aspects, FIGS. 2A and 2B merely show some elements of the semiconductor structure 200 for illustration purposes, and other elements above and/or below the elements shown in FIGS. 2A and 2B may be disposed but not shown in FIGS. 2A and 2B. Moreover, the elements that are the same or similar to those in FIG. 1 are given the same reference numbers, and detailed description thereof may be omitted.

As shown in FIG. 2A, compared to the semiconductor structure 100, the semiconductor structure 200 does not include the contacts 133, 134, and 137, the conductive structures 142 and 144, and the corresponding via structures. In some aspects, compared to the semiconductor structure 100, the contacts and interconnects formed based on these omitted elements may be replaced by backside contacts and backside interconnects. In some aspects, the backside contacts and the backside interconnects may correspond to the contacts and interconnects disposed below the S/D structures and/or gate stacks in the vertical direction and may be formed from the back side of the semiconductor structure.

As shown in FIG. 2B, the semiconductor structure 200 includes a backside contact 233 electrically coupling the S/D structure 123 of the third transistor to a backside conductive structure 242, a backside contact 234 electrically coupling the S/D structure 124 of the first transistor to the backside conductive structure 242, and a backside contact 237 electrically coupling the S/D structure 127 of the fourth transistor to a backside conductive structure 244. In some aspects, the backside conductive structure 242 may be configured to carry the first power voltage (e.g., VDD), and the backside conductive structure 244 may be configured to carry the second power voltage (e.g., VSS or ground).

In some aspects, scaling of logic components may become ineffective due to slowed pitch scaling and lack of material breakthrough. In some aspects, front-side only technology (e.g., the example illustrated with reference to FIG. 1) or power via buried power rail may have higher middle-of-line (MOL) capacitance, which may limit the achievable level of power reduction.

In some aspects, one of promising future directions for continued scaling is based on a gate-all-around backside power distribution network (GAA-BSPDN) technology (e.g., the example illustrated with reference to FIGS. 2A and 2B), where the contacts of the S/D structures (i.e., S/D contacts or diffusion contacts) and/or local interconnects may be formed directly from the back side of the semiconductor structure. In some aspects, a diffusion contact formed from the back side may be referred to as a backside contact (BSC), and a local interconnect formed from the back side may be referred to as a backside contact local interconnect (BSCLI). In some aspects, with more than half of the diffusion contacts and/or local interconnects being implemented as BSCs and/or BSCLIs, gate-to-contact parasitic capacitance may be greatly reduced. In some aspects, the amount of capacitance improvement may be significant, e.g., equivalent to about half of the whole manufacturing technology node reduction.

Accordingly, the present application further describes methods of manufacturing the BSCLIs as a jumper extending along one direction to connect two BSCs and/or BSCLIs extending along another direction (e.g., also referred to as “backside bi-directional interconnects” in this disclosure). In some aspects, the backside bi-directional interconnects may be formed based on a self-aligned conductive structure. In some aspects, the backside bi-directional interconnects may be formed based on a dielectric structure that is an area specific deposition (ASD) structure or a etch stop layer.

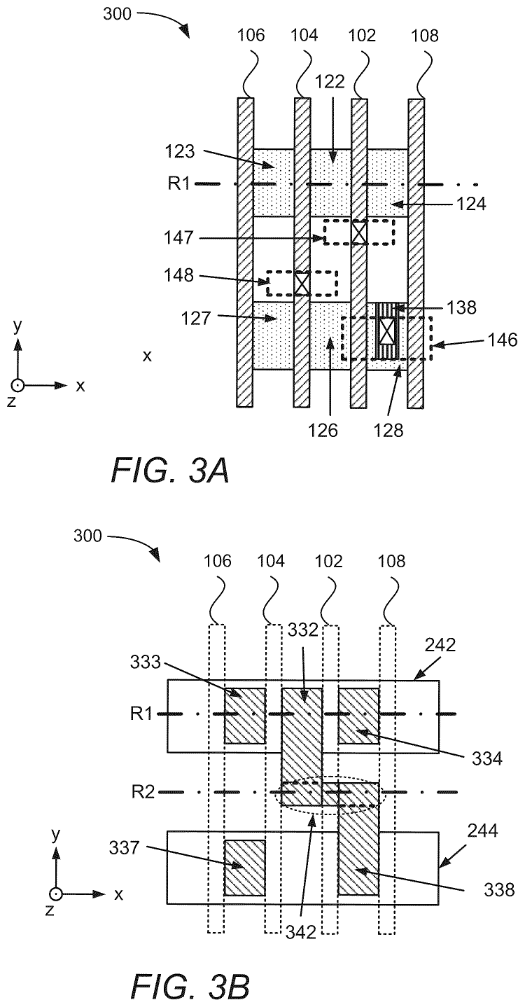

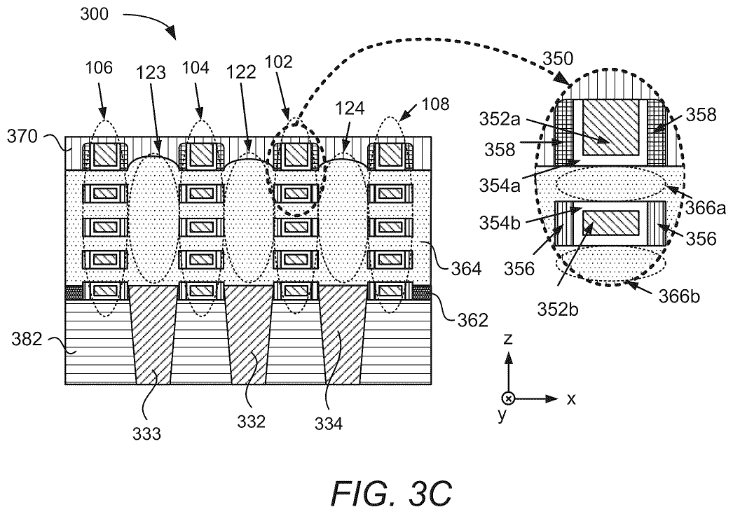

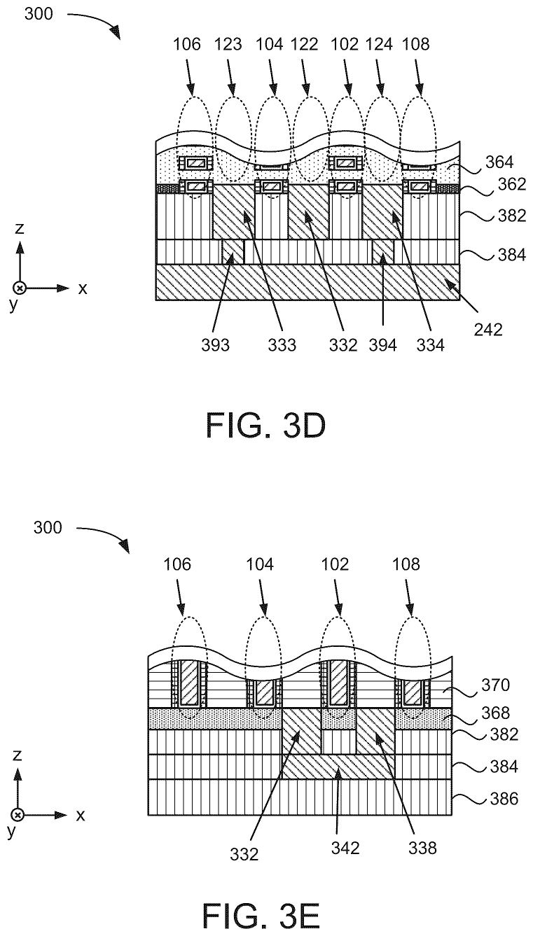

FIGS. 3A and 3B are top views of a portion of a semiconductor structure 300 of an IC device, with emphasis of elements at different vertical regions thereof, according to aspects of the disclosure. In particular, the elements shown in FIG. 3A show the elements that may be above the elements shown in FIG. 3B in a vertical direction (e.g., the z direction corresponding to a direction leaving the plane of the drawing sheet). In some aspects, FIGS. 3A and 3B merely show some elements of the semiconductor structure 300 for illustration purposes, and other elements above and/or below the elements shown in FIGS. 3A and 3B may be disposed but not shown in FIGS. 3A and 3B. Moreover, in some aspects, the semiconductor structure 300 may be a NAND gate variation of the example depicted in FIGS. 1-2B. As such, the elements that are the same or similar to those in FIGS. 1-2B are given the same reference numbers, and detailed description thereof may be omitted.

As shown in FIG. 3A, the S/D structures 124 and 122 are adjacent a first gate structure of the gate stack 102, and the S/D structures 126 and 128 are adjacent a second gate structure of the gate stack 102. As shown in FIG. 3A, compared to the semiconductor structure 200, the semiconductor structure 300 does not include the contact 132, the conductive structures 145 and 152, and the corresponding via structures. In some aspects, compared to the semiconductor structure 200, the contacts and interconnects formed based on these omitted elements may be replaced by backside contacts and backside interconnects (e.g., backside conductive structures).

As shown in FIG. 3B, the semiconductor structure 300 includes a backside conductive structure 332 electrically coupling the S/D structure 122 of the first transistor and the third transistor and a backside conductive structure 338 electrically coupling the S/D structure 128 of the second transistor. Also, the semiconductor structure 300 includes a backside conductive structure 333 and a corresponding via structure (not shown) electrically coupling the S/D structure 123 of the third transistor to a backside conductive structure 242, a backside conductive structure 334 and a corresponding via structure (not shown) electrically coupling the S/D structure 124 of the first transistor to the backside conductive structure 242, and a backside conductive structure 337 and a corresponding via structure (not shown) electrically coupling the S/D structure 127 of the fourth transistor to a backside conductive structure 244.

In some aspects, the backside conductive structure 332 may extend along the first direction toward the S/D structure 126, and the backside conductive structure 338 may extend along the first direction toward the S/D structure 124. Moreover, the semiconductor structure 300 further includes a backside conductive structure 342 under and in contact with the backside conductive structures 332 and 338. In some aspects, the backside conductive structure 342 may be configured as a jumper electrically connecting the backside conductive structures 332 and 338.

FIG. 3C is a cross-sectional view of a portion of the semiconductor structure 300 of FIGS. 3A and 3B along a cut line R1, according to aspects of the disclosure. Elements in FIG. 3C that are the same or similar to those in FIGS. 3A and 3B are given the same reference numbers, and detailed description thereof may be omitted.

As shown in FIG. 3C, the semiconductor structure 300 includes gate stacks 102, 104, 106, and 108. An enlarged area 350 showing the details of a portion of the gate stack 102. In some aspects, the gate stacks 104, 106, and 108 may have a configuration similar to the configuration of the gate stack 102. As shown in FIG. 3C, the gate stack 102 may include five gate portions each including a respective gate electrode (also called “gate metal” or “gate conductor”) (e.g., gate electrode 352a or 352b) and a respective gate dielectric structure (e.g., gate dielectric structure 354a or 354b). In this disclosure, all the gate electrodes in a gate stack may be collectively referred to as a gate electrode structure. In some aspects, a top gate portion of the gate stack 102 may include gate spacers 358 on sidewalls of the gate dielectric structure 354a. In some aspects, the gate portions of the gate stack 102 other than the top gate portion may include inner spacers (e.g., inner spacers 356) on sidewalls of the respective gate dielectric structure (e.g., gate dielectric structure 354b).

The semiconductor structure 300 may include an epitaxial stop layer 362. In some aspects, a lower surface of the epitaxial stop layer 362 may be at about the same level of a lower surface of the gate structures of the gate stacks 102, 104, 106, and 108. The semiconductor structure 300 may further include an epitaxial layer 364. The portion of the epitaxial layer 364 between the gate stacks 102 and 104 may define the S/D structure 122; the portion of the epitaxial layer 364 between the gate stacks 104 and 106 may define the S/D structure 123; and the portion of the epitaxial layer 364 between the gate stacks 102 and 108 may define the S/D structure 124. Moreover, the portions of the gate stacks 102, 104, 106, and/or 108 between adjacent gate portions may be configured as channel members (e.g., channel members 366a and 366b). In this disclosure, all the channel members in a gate stack may be collectively referred to as a channel structure. In some aspects, the channel members may comprise a plurality of nanowires or nanosheets.

As shown in FIG. 3C, the semiconductor structure 300 may include a front side dielectric layer 370 (e.g., a front side ILD layer) on the gate stacks 102, 104, 106, and 108 and the epitaxial layer 364. In some aspects, for the convenience of illustration, the elements that are at or above the lower surface of the epitaxial stop layer 362 and/or the lower surface of the gate structures of the gate stacks 102, 104, 106, and 108 may be referred to as in a front portion of the semiconductor structure 300; and the elements that are below the lower surface of the epitaxial stop layer 362 and/or the lower surface of the gate structures of the gate stacks 102, 104, 106, and 108 may be referred to as in a back portion of the semiconductor structure 300 opposing the front portion.

As shown in FIG. 3C, the semiconductor structure 300 may further include a backside dielectric layer 382 (e.g., a backside ILD layer) in the back portion of the semiconductor structure 300. The backside conductive structures 332, 333, and 334 may be disposed at least partially in the back portion of the semiconductor structure and through the backside dielectric layer 382. Moreover, the backside conductive structure 332 may extend along the first direction (e.g., the y direction) and electrically coupled to the S/D structure 128 through backside conductive structures 338 and 342 (not shown in FIG. 3C).

As shown in FIG. 3C, in some aspects, an upper portion of the backside conductive structure (e.g., the backside conductive structure 332) may be in contact with a bottom inner spacer of a gate structure (e.g., the gate structure of the gate stack 102) and a bottom inner spacer of another gate structure (e.g., the gate structure of the gate stack 104 that is offset from the gate structure of the gate stack 102 in the x direction). In some aspects, the backside conductive structures may comprise tungsten, cobalt, molybdenum, or a combination thereof.

FIG. 3D is a cross-sectional view of a portion of the semiconductor structure 300 of FIGS. 3A and 3B along a cut line R1, with details of the gate stacks 102, 104, 106, and 108 simplified, according to aspects of the disclosure. FIG. 3E is a cross-sectional view of a portion of the semiconductor structure 300 of FIGS. 3A and 3B along a cut line R2, with details of the gate stacks 102, 104, 106, and 108 simplified, according to aspects of the disclosure. Elements in FIGS. 3D and 3E that are the same or similar to those in FIGS. 3A-3C are given the same reference numbers, and detailed description thereof may be omitted.

As shown in FIG. 3D, the backside conductive structure 332 is in contact with the S/D structure 122; the backside conductive structure 333 is in contact with the S/D structure 123; and the backside conductive structure 334 is in contact with the S/D structure 124. In some aspects, the backside conductive structures 332, 333, and 334 are partially embedded in the backside dielectric layer 382. In some aspects, the backside dielectric layer 382 and the corresponding metallization structures disposed therein may be referred to as a first backside metallization layer under the S/D structures.

The semiconductor structure 300 further includes via structures 393 and 394 embedded in a backside dielectric layer 384 under the backside dielectric layer 382 and a backside conductive structure 242 embedded in a backside dielectric layer 386 (FIG. 3E) under the backside dielectric layer 384. In some aspects, the backside dielectric layer 384 and the corresponding metallization structures disposed therein may be referred to as a second backside metallization layer under the first backside metallization layer. In some aspects, the backside dielectric layer 386 and the corresponding metallization structures disposed therein may be referred to as a third backside metallization layer under the second backside metallization layer. The via structures 393 and 394 electrically connect the backside conductive structures 332 and 334 to the backside conductive structure 242, respectively. Also, the backside conductive structure 332 is electrically isolated from the backside conductive structure 242 by the backside dielectric layer 384.

As shown in FIG. 3E, an isolation structure 368 (e.g., shallow trench isolation (STI) structures) may be disposed under the epitaxial stop layer 362 and/or the front side dielectric layer 370 in the area not overlapping the S/D structures and channel structures of the first, second, third, and fourth transistors (from a top view). The backside conductive structure 332 is in contact with the S/D structure 122 (as shown in FIG. 3D); and the backside conductive structure 338 is in contact with the S/D structure 126 (not shown). In some aspects, the backside conductive structures 332 and 338 are partially embedded in the backside dielectric layer 382. The semiconductor structure 300 further includes the backside conductive structure 342 embedded in the backside dielectric layer 384 under the backside dielectric layer 382 (e.g., in the second backside metallization layer). In some aspects, the backside conductive structures 332 and 338 may extend along the first direction (e.g., the y direction). In some aspects, the backside conductive structure 342 may extend along the second direction (e.g., the x direction) and in contact with the backside conductive structures 332 and 338.

Accordingly, as shown in FIGS. 3A-3E, the semiconductor structure 300 may include the backside conductive structure 332 in contact with the S/D structure 122 and disposed at least partially in the back portion of the semiconductor structure opposing the front portion; the backside conductive structure 338 in contact with the S/D structure 128 and disposed at least partially in the back portion of the semiconductor structure; and the backside conductive structure 342 disposed in the back portion of the semiconductor structure, extending along the second direction, and in contact with the backside conductive structure 332 and the backside conductive structure 338. In some aspects, the backside conductive structure 332 and the backside conductive structure 338 may be disposed within a first backside metallization layer under the S/D structure 122 and the S/D structure 128, and the backside conductive structure 342 may be disposed within a second backside metallization layer under the first backside metallization layer. In some aspects, the backside conductive structure (e.g., the via structures 393 and 394) may be disposed within the second backside metallization layer. In some aspects, a metallization structure (e.g., the backside conductive structure 242 or 244) may be disposed within a third backside metallization layer under the second backside metallization layer. In some aspects, one or more via structures may be configured to connect the metallization structure to another backside conductive structure in the first backside metallization layer.

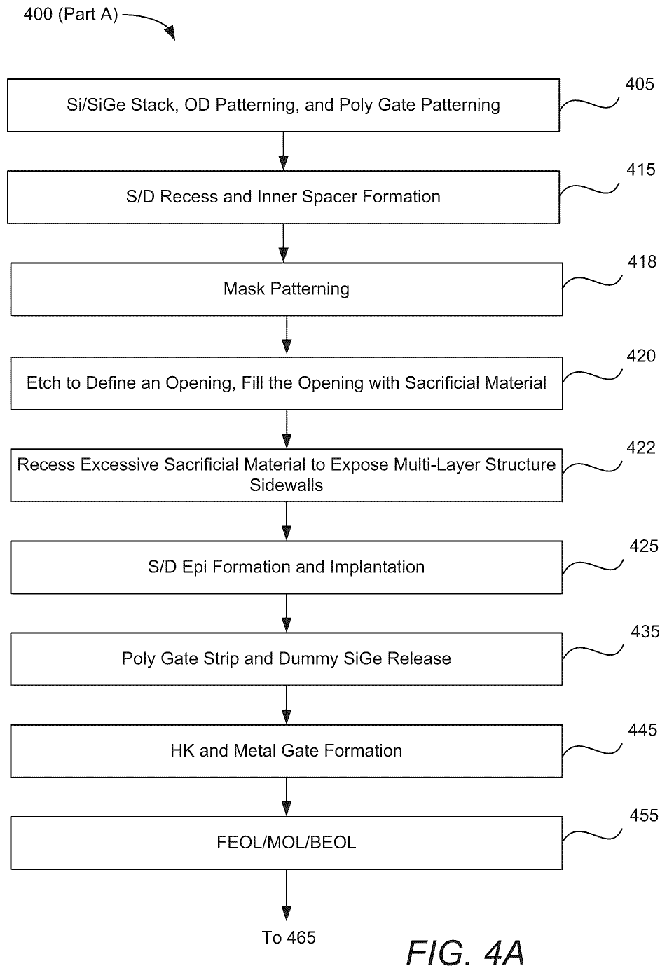

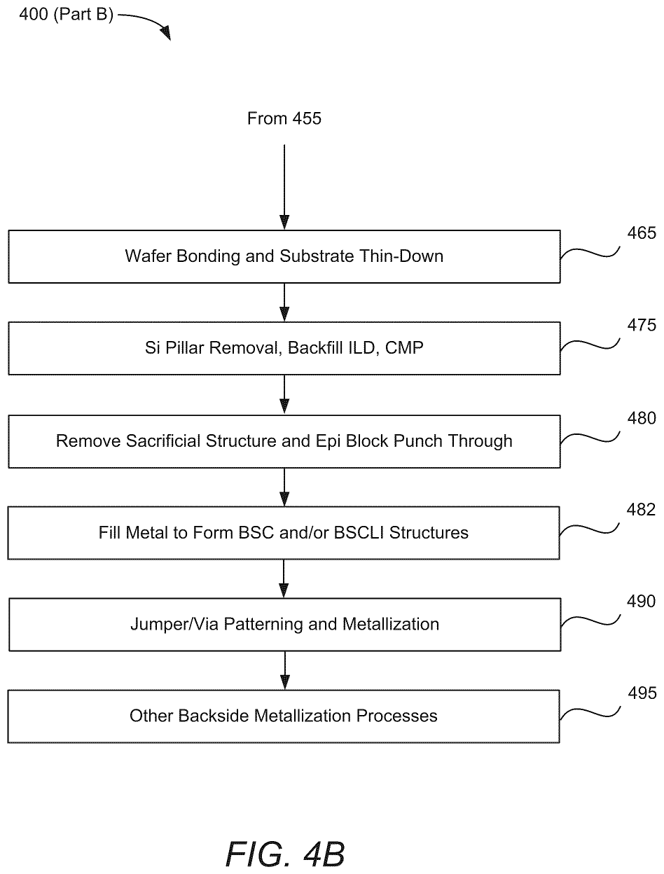

FIGS. 4A and 4B illustrate a manufacturing process 400 for manufacturing a semiconductor structure (e.g., the semiconductor structure 300 in FIGS. 3A-3E), according to aspects of the disclosure. In some aspects, the processing stages shown in FIG. 4A (labeled as “Part A” of the manufacturing process 400) may correspond to front-side processing of the semiconductor structure, as these stages may correspond to processes performed from a front side of a wafer on which the semiconductor structure is formed. In some aspects, the processing stages shown in FIG. 4B (labeled as “Part B” of the manufacturing process 400) may correspond to back-side processing of the wafer, as these stages may correspond to processes performed from a back side of the wafer opposing the front side of the wafer.

At stage 405, a multi-layer structure may be formed on a substrate of a wafer. In some aspects, the multi-layer structure may include layers of different silicon materials stacked one over another. In some aspects the multi-layer structure may include layers of silicon (Si) and silicon germanium (SiGe) stacked one over another as a Si/SiGe stack.

At stage 405, an active area of the semiconductor structure may be defined based on an oxide diffusion (OD) pattern. In some aspects, an OD patterning process may be performed on the multi-layer structure (e.g., the Si/SiGe stack) to shape the multi-layer structure into a fin-like structure. At stage 405, a layer of polysilicon material may be formed on the fin-like structure, and a poly gate patterning process may be performed on the layer of polysilicon material to form a patterned polysilicon structure on the fin-like structure. In some aspects, the patterned polysilicon structure may extend along a first direction (e.g., the y direction in FIGS. 3A-3E). In some aspects, a polysilicon gate structure may be formed based on the patterned polysilicon structure and may further include outer spacers formed on both sides of the patterned polysilicon structure in a second direction (e.g., the x direction in FIGS. 3A-3E).

At stage 415, a source/drain (S/D) recess process is performed on the fin-like structure using at least the polysilicon gate structure as a mask. The resulting structure after the S/D recess process may include a trimmed multi-layer structure substantially flush with the polysilicon gate structure on the sides in the second direction. In some aspects, an inner spacer formation process is performed based on partially and selectively removing a portion of the multi-layer structure (e.g., selectively removing SiGe over Si) exposed in the second direction and filling the removed portion of the multi-layer structure with a dielectric material to form a plurality of inner spacers.

At stage 418, a mask patterning process is performed to form a resist pattern with an opening based on the positions where the backside conductive structures may be formed. As the backside conductive structures may be formed as self-aligned contact structures, the positions where the backside conductive structures may be defined based on the combination of the resist pattern and the polysilicon gate structure.

At stage 420, an etching process is performed using the resist pattern and the polysilicon gate structure as a mask to define an opening corresponding to the positions where the backside conductive structures may be formed. At stage 420, the opening is further filled with a sacrificial material. At stage 422, the portion of the filled sacrificial material that may cover the sidewalls of the trimmed multi-layer structure may be recessed to the extent that will not hinder to subsequent electrical coupling to the channel members (e.g., to expose at least the sidewalls of the trimmed multi-layer structure not covered by the inner spacers).

At stage 425, an S/D epi formation process is performed to form epitaxially grown structures on both sides of the polysilicon gate structure in the second direction. In some aspects, the epitaxially grown structures may include Si. In some aspects, one or more implantation processes may be performed on the epitaxially grown structures to convert the epitaxially grown structures into S/D structures. In some aspects, an epitaxial stop layer may be formed before forming the epitaxially grown structures.

At stage 435, a poly gate strip process may be performed on the polysilicon gate structure to remove at least the polysilicon portion of the polysilicon gate structure. Afterwards, a removal process may be performed to remove the same material of the multi-layer structure removed at stage 415, which converts the multi-layer structure into a channel structure that may include one or more channel members. In some aspects, the multi-layer structure is a Si/SiGe stack, and SiGe is removed at stage 435 (also referred to as a dummy SiGe release process). After stage 435, an opening between the outer spacers and the inner spacers may be defined, with the one or more channel members passing through the opening from side to side in the second direction.

At stage 445, a high dielectric constant (high-k or HK) metal gate structure is formed in the opening from stage 435 and surrounding the one or more channel members. In some aspects, the HK metal gate structure includes a gate electrode structure and one or more gate dielectric structures between the gate electrode structure and the respective one or more channel members. In some aspects, the one or more gate dielectric structures may include a dielectric material or a dielectric structure that corresponds to a dielectric constant greater than a dielectric constant of silicon (hence referred to as HK).

At stage 455, one or more of a front end of line (FEOL) process, a middle of line (MOL) process, or back end of line (BEOL) process may be performed on the resulting structure of stage 445 in order to form a plurality layers of metallization structures. In some aspects, the FEOL process may correspond to forming conductive vias or contacts on the electrical components in order to prepare the electrical components for interconnection. In some aspects, the MOL process may be performed after the FEOL process and may correspond to forming conductive vias and conductive lines for local interconnections among neighboring electrical components. In some aspects, the BEOL process may be performed after the MOL process and may correspond to forming conductive vias and conductive lines for interconnections among groups of electrical components. In some aspects, the MOL process may be omitted, and the local interconnections may be formed based on the FEOL process, the BEOL process, or both.

After the front-side processing of the semiconductor structure as shown in FIG. 4A, the back-side processing of the semiconductor structure is shown in FIG. 4B.

At stage 465, a carrier may be attached to the front side of the wafer from stage 455 during a wafer bonding process. The wafer with carrier attached thereon may be flipped upside down so the substrate on the back side of the wafer now may face up. Afterwards, a substrate thin-down process may be performed to remove at least a portion of the substrate of the wafer.

At stage 475, the remaining of the substrate material may be further, selectively removed during a silicon pillar removal process and leaving structures such as etch stop layers, STI structures, and/or other structures (such as a placeholder or sacrificial via structure). Afterwards, a backside ILD layer may be formed by filling an ILD material from the back side of the wafer. In some aspects, a further chemical-mechanical polishing (CMP) process may be performed to trim the thickness of the backside ILD layer.

At stage 480, the sacrificial structures formed at stage 422 may be exposed after stage 475 and may be removed from the back side of the wafer. At stage 480, a portion of the epitaxial stop layer under the S/D structures and exposed after the removal of the sacrificial structures may be further removed based on an epi stop punch through process. After stage 480, backside openings thus may be defined based on the removal of the sacrificial structures and the removal of the portion of the epitaxial stop layer under the S/D structures.

At stage 482, the backside opening from stage 480 may be filled with a conductive or metallic material to form the backside conductive structures 332, 333, 334, 337, and 338 illustrated in FIGS. 3A-3E.

At Stage 490, an additional backside dielectric layer (e.g., the backside dielectric layer 384) is formed and patterned to define the openings for forming the via structures and the jumper (e.g., the backside conductive structure 342) in a patterning process, and the openings are filled with one or more conductive materials in a metallization process to form the via structures and the jumper.

At stage 495, other backside metallization processes may be performed to form additional metallization layers, including one or more power lines (e.g., the backside conductive structures 242 and 244) and/or one or more signal lines. In some aspects, one or more conductive pads may be formed, where a resulting integrated circuit device based on the semiconductor structure described herein may be attached to another integrated circuit device, an interposer, or a packaging substrate through the one or more conductive pads.

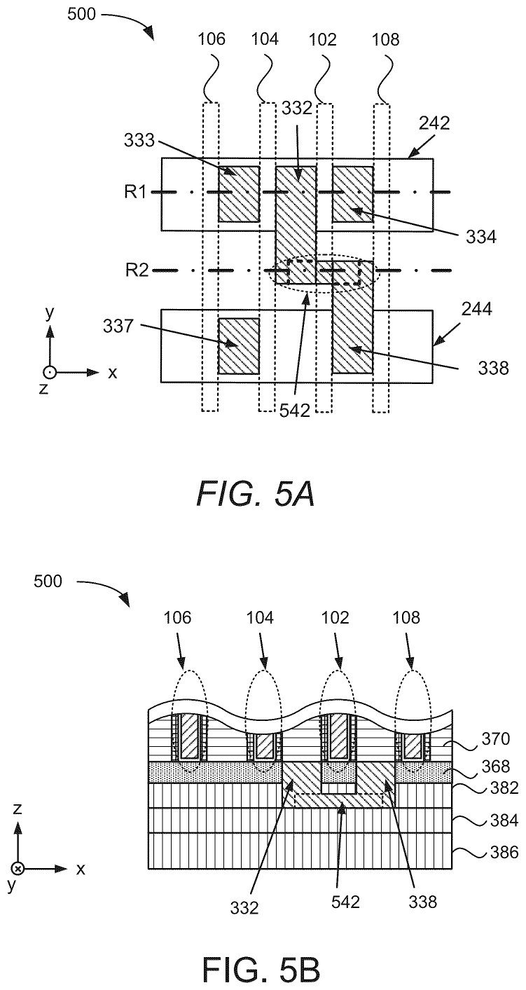

FIG. 5A is a top view of a portion of a semiconductor structure 500 of an IC device, according to aspects of the disclosure. In some aspects, the semiconductor structure 500 may be a variation of the semiconductor structure 300, and the portion of semiconductor structure 500 that are above the elements shown in FIG. 5A may correspond to the portion of semiconductor structure 300 depicted in FIG. 3A. In some aspects, FIG. 5A in combination of FIG. 3A merely show some elements of the semiconductor structure 500 for illustration purposes, and other elements above and/or below the elements shown in FIGS. 5A and 3A may be disposed but not shown in FIGS. 5A and 3A.

Also, in some aspects, a cross-sectional view of the semiconductor structure 500 along a cut line R1 may correspond to the semiconductor structure 300 depicted in FIG. 3D. The elements that are the same or similar to those in FIGS. 3A-3E are given the same reference numbers, and detailed description thereof may be omitted.

As shown in FIG. 5A, compared to the semiconductor structure 300 depicted in FIG. 3B, the semiconductor structure 500 includes a backside conductive structure 542 in place of the backside conductive structure 342 in FIG. 3B. Compared with the backside conductive structure 342 that is disposed in a backside metallization layer under the backside conductive structures 332 and 338, the backside conductive structure 542 may be disposed within the same backside metallization layer in which the conductive structures 332 and 338 are at least partially disposed.

FIG. 5B is a cross-sectional view of a portion of the semiconductor structure 500 of FIG. 5A along a cut line R2, with details of the gate stacks 102, 104, 106, and 108 simplified, according to aspects of the disclosure. As shown in FIG. 5B, the backside conductive structure 542 may be disposed at a lower portion of the same backside metallization layer (i.e., based on the backside dielectric layer 382) in which the conductive structures 332 and 338 at least partially disposed. In some aspects, the backside conductive structure 542 may be integrally formed with the backside conductive structures 332 and 338.

Accordingly, as shown in FIGS. 5A-5B, the semiconductor structure 500 may include the backside conductive structure 332 in contact with the S/D structure 122 and disposed at least partially in the back portion of the semiconductor structure opposing the front portion; the backside conductive structure 338 in contact with the S/D structure 128 and disposed at least partially in the back portion of the semiconductor structure; and the backside conductive structure 542 disposed in the back portion of the semiconductor structure, extending along the second direction, and in contact with the backside conductive structure 332 and the backside conductive structure 338. In some aspects, the backside conductive structure 332 and the backside conductive structure 338 may be disposed within a first backside metallization layer under the S/D structure 122 and the S/D structure 128, and the backside conductive structure 542 may be disposed within a lower portion of the first backside metallization layer. In some aspects, the backside conductive structure (e.g., the via structures 393 and 394) may be disposed within the second backside metallization layer. In some aspects, a metallization structure (e.g., the backside conductive structure 242 or 244) may be disposed within a third backside metallization layer under the second backside metallization layer. In some aspects, one or more via structures may be configured to connect the metallization structure to another backside conductive structure in the first backside metallization layer.

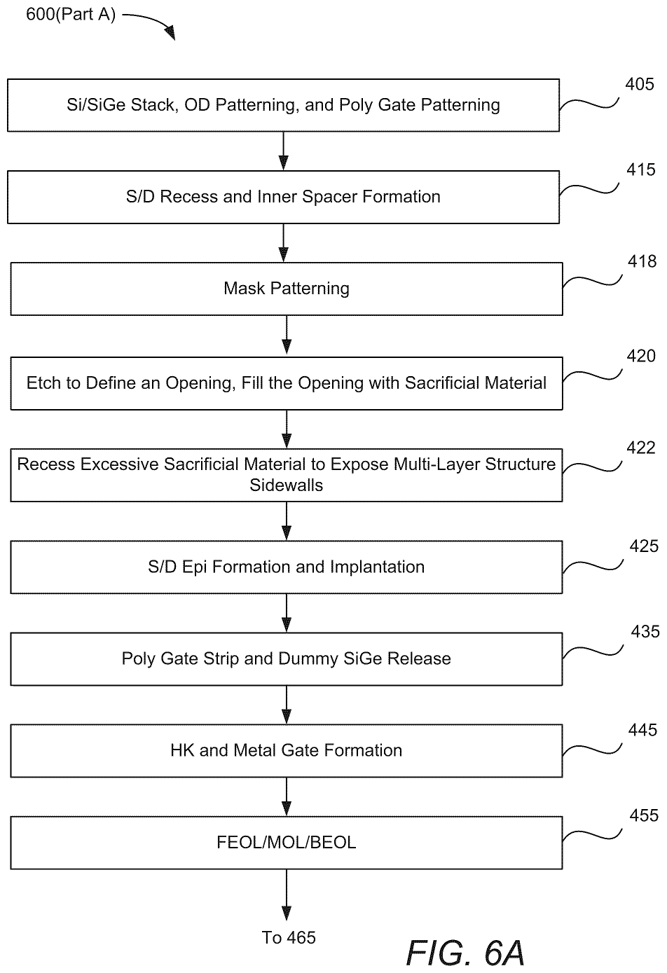

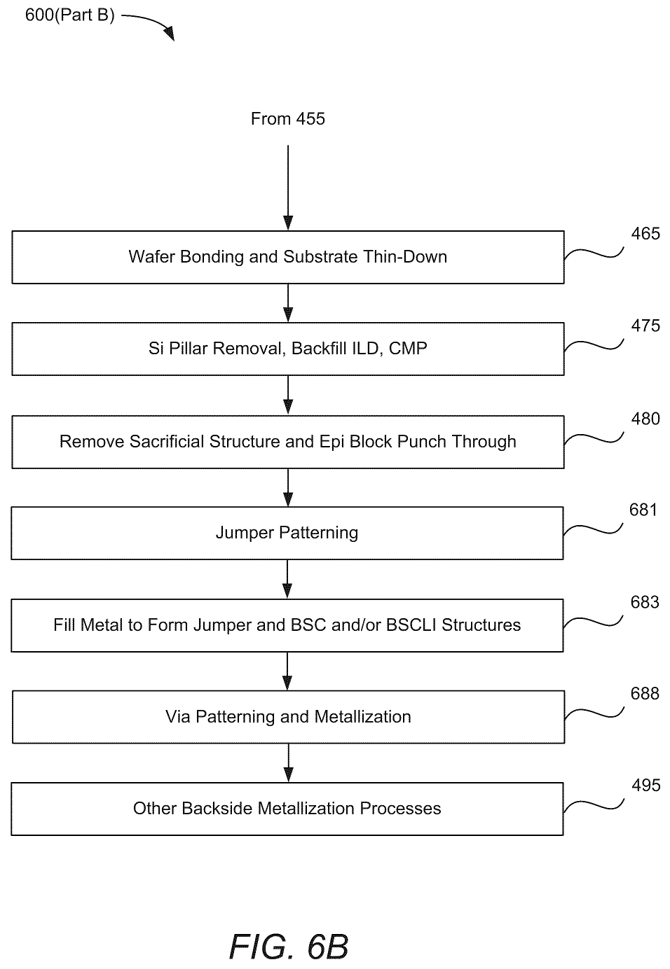

FIGS. 6A and 6B illustrate a manufacturing process 600 for manufacturing a semiconductor structure (e.g., the semiconductor structure 500 in FIGS. 5A-5B), according to aspects of the disclosure. In some aspects, the processing stages shown in FIG. 6A (labeled as “Part A” of the manufacturing process 600) may correspond to front-side processing of the semiconductor structure, as these stages may correspond to processes performed from a front side of a wafer on which the semiconductor structure is formed. In some aspects, the processing stages shown in FIG. 6B (labeled as “Part B” of the manufacturing process 600) may correspond to back-side processing of the wafer, as these stages may correspond to processes performed from a back side of the wafer opposing the front side of the wafer.

In some aspects, the process 600 may be a variation of the process 400 in FIGS. 4A-4B. The stages that are the same or similar to those in FIGS. 4A-4B are given the same reference numbers, and detailed description thereof may be omitted. In some aspects, the process may include stages 405, 415, 418, 420, 422, 425, 435, 445, 455, 465, 475, and 480 that are the same or similar to the corresponding counterparts illustrated with reference to FIGS. 4A-4B.

After stage 480, at stage 681 in FIG. 6B, a jumper patterning process is performed to modify the backside openings from stage 480 to further include a jumper opening portion for forming the backside conductive structure that is configured as a jumper (e.g., the backside conductive structure 542).

At stage 683, the modified backside opening from stage 681 may be filled with a conductive or metallic material to form the backside conductive structures 332, 333, 334, 337, and 338 illustrated in FIGS. 5A-5B together with the backside conductive structure 542.

At stage 688, an additional backside dielectric layer (e.g., the backside dielectric layer 384) is formed and patterned to define the openings for forming the via structures in a patterning process, and the openings are filled with one or more conductive materials in a metallization process to form the via structures.

After stage 688, at stage 495, other backside metallization processes may be performed to form additional metallization layers, including one or more power lines (e.g., the backside conductive structures 242 and 244) and/or one or more signal lines. In some aspects, one or more conductive pads may be formed, where a resulting integrated circuit device based on the semiconductor structure described herein may be attached to another integrated circuit device, an interposer, or a packaging substrate through the one or more conductive pads.

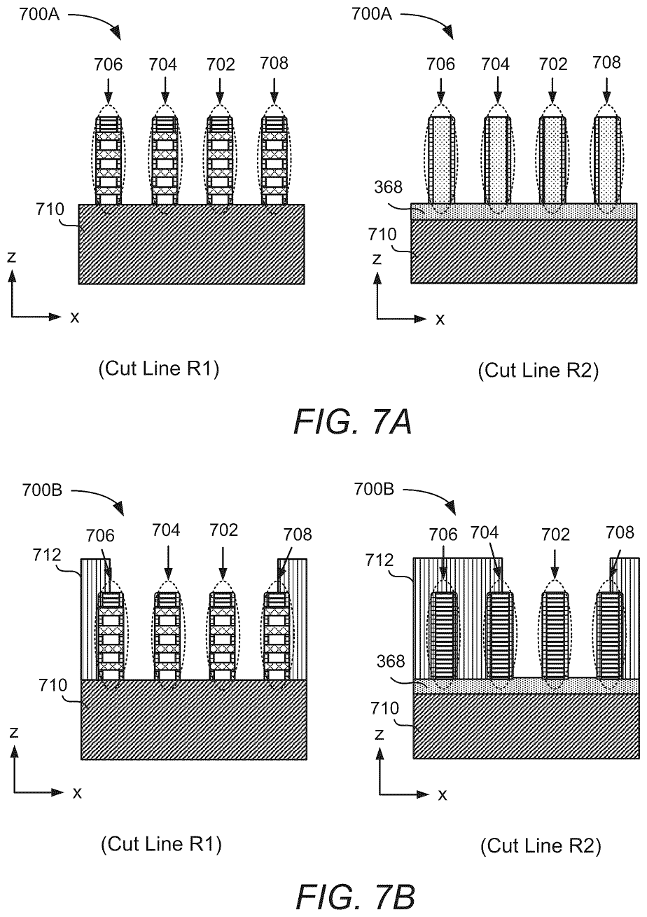

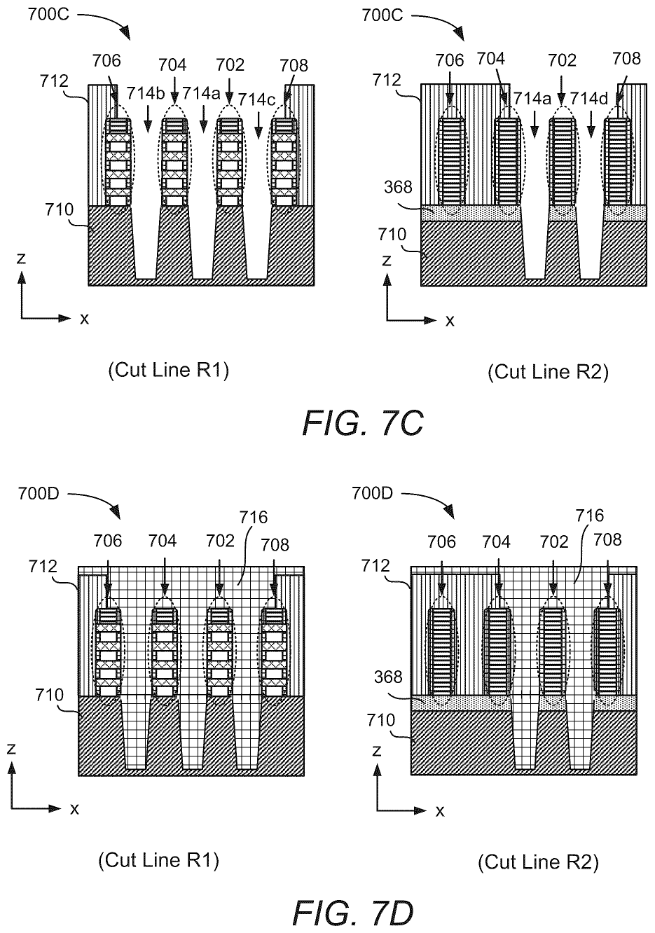

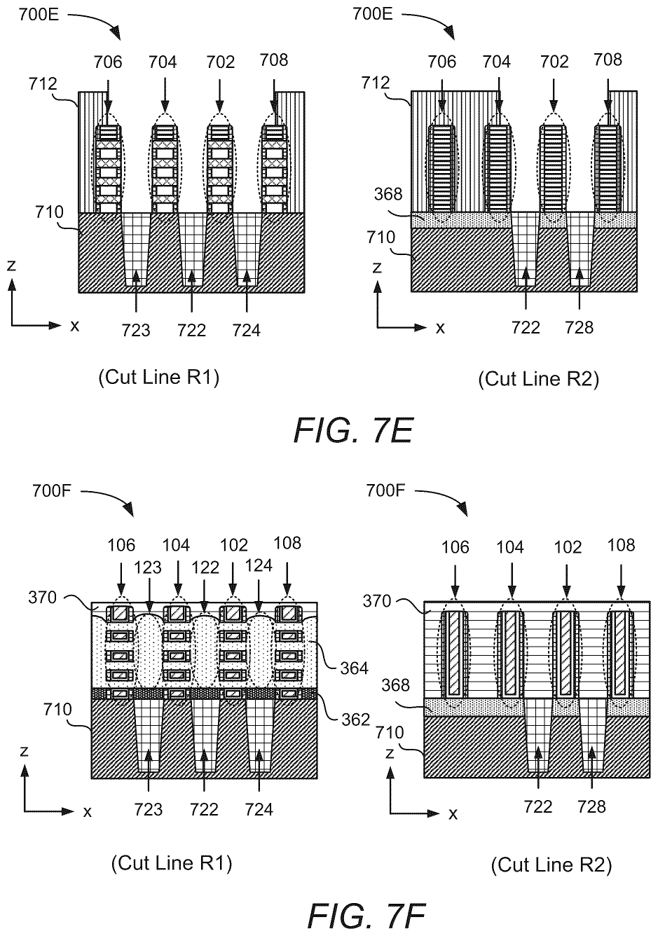

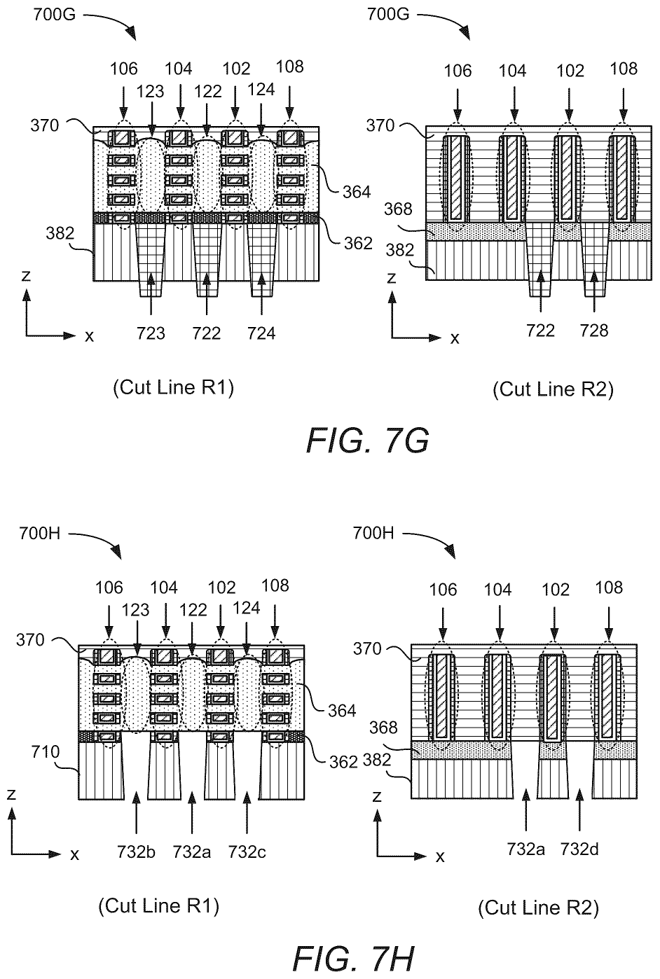

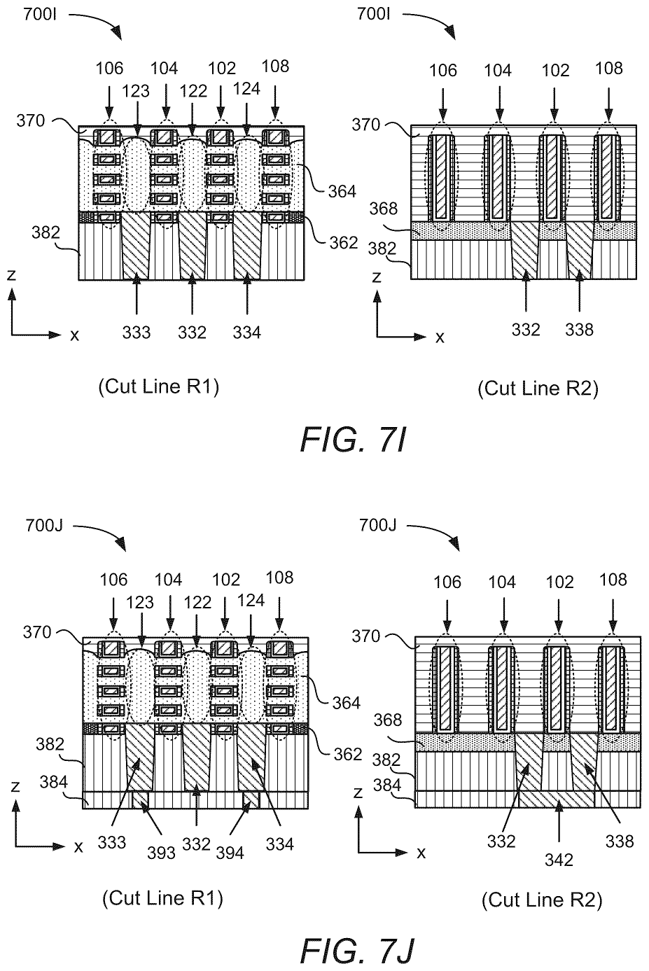

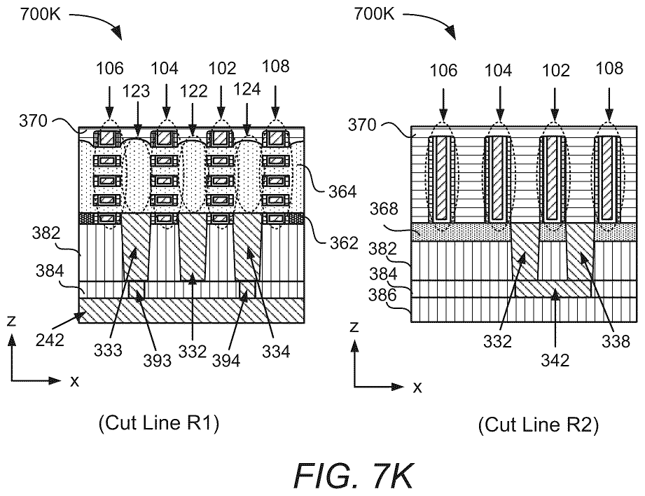

FIGS. 7A-7K illustrate structures at various stages of manufacturing a semiconductor structure of FIGS. 3A-3E, according to aspects of the disclosure. Each one of FIGS. 7A-7K includes a cross-sectional view (denoted “Cut Line R1”) on the left that is taken along a cut line corresponding to the cut line R1 in FIG. 3B; and a cross-sectional view (denoted “Cut Line R2”) on the right that is taken along a cut line corresponding to the cut line R2 in FIG. 3B. The elements illustrated in FIGS. 7A-7K that are the same or similar to those of FIGS. 3A-3E are given the same reference numbers, and the detailed description thereof may be omitted.

As shown in FIG. 7A, a structure 700A is provided. The structure 700A includes four gate stacks 702, 704, 706, and 708 on a substrate 710. Also, an STI structure 368 may be embedded in the substrate 710 in the area outside the active areas that correspond to the S/D structures and channel structures of the resulting transistors. In some aspects, the gate stacks 702, 704, 706, and 708 may correspond to the resulting structure of the gate stacks at stage 415 in FIG. 4A.

As shown in FIG. 7B, a structure 700B is formed based on the structure 700A by forming a resist pattern 712 that defines an opening based on the positions where the backside conductive structures (e.g., the backside conductive structures 332, 333, 334, and 338) may be formed. In some aspects, the resist pattern 712 may be formed by first forming a photoresist material over the structure 700A, then performing a lithographic process to develop an exposed portion of the photoresist material, and either removing the exposed portion or an exposed portion of the photoresist material (depending on the type of the photoresist material and/or the removal process) to form the resist pattern 712. In some aspects, the structure 700B may correspond to the resulting structure at stage 418 in FIG. 4A.

As shown in FIG. 7C, a structure 700C is formed based on the structure 700B by forming an etching process based using the gate stacks 702, 704, 706, and 708 and the resist pattern 712 as a mask to define openings 714a-714d corresponding to the positions where the backside conductive structures (e.g., the backside conductive structures 332, 333, 334, and 338) may be formed. In some aspects, the etching process may include multiple steps, including a first step removing a portion of the substrate 710 not covered by the STI structure 368, a second step removing a portion of the STI structure 368, and a third step further extending the opening within the substrate 710. In some aspects, the etching process may include a step of non-selective etching to etch deep enough into the substrate 710 under the STI structure 368. In some aspects, the structure 700C may correspond to the resulting structure of the first half of stage 420 in FIG. 4A.

As shown in FIG. 7D, a structure 700D is formed based on the structure 700C by filling a sacrificial material into the openings 714a-714d to form the filled sacrificial material 716. In some aspects, the sacrificial material may have a preferred selectivity over a dielectric material (e.g., silicon oxide) for forming the backside dielectric layer (e.g., the backside ILD layer 382) during a subsequent sacrificial material removal process (e.g., at stage 480). In some aspects, the sacrificial material may be filled based on a spin-on process. In some aspects, the sacrificial material may include silicon nitride (SiN), which may be highly selective over Si, SiGe, and/or silicon oxide during certain etch processes. In some aspects, the structure 700D may correspond to the resulting structure of stage 420 in FIG. 4A.

As shown in FIG. 7E, a structure 700E is formed based on the structure 700D by performing a recess process to remove excessive sacrificial material to at least expose the sidewalls of the multilayer structure of the gate stacks 702, 704, 706, and 708 that correspond to channel members thereof. The remaining of the filled sacrificial material from the structure 700D becomes sacrificial structures 722, 723, 724, and 728. In some aspects, the sacrificial structures 722, 723, 724, and 728 may be used as placeholders for the backside conductive structures 332, 333, 334, and 338, respectively. In some aspects, the structure 700E may correspond to the resulting structure of stage 422 in FIG. 4A.

As shown in FIG. 7F, a structure 700F is formed based on the structure 700E by performing the operations corresponding to stages 425, 435, and 445. As a result, the epitaxial stop layer 362 is formed, the epitaxial layer 364 is formed, the gate stacks 102, 104, 106, and 108 with HK metal gate structures and channel structures are formed, and the corresponding S/D structures (e.g., S/D structures 122, 123, 124, 126, 127, and 128) are formed. In some aspects, the structure 700F may correspond to the resulting structure of stage 445 in FIG. 4A.

As shown in FIG. 7G, a structure 700G is formed based on the structure 700F. In some aspects, one or more of FEOL process, MOL process, or BEOL process may be performed on the structure 700F from the front side, and the wafer on which the semiconductor structure 700F is formed may be bonded to a carrier and flipped for various further processes from the back side. In some aspects, a substrate thin-down process may be performed from the back side to remove at least a portion of the substrate 710, and the rest of the substrate 710 may be further removed during a silicon pillar removal process. Afterwards, the backside dielectric layer 382 may be formed. In some aspects, the backside dielectric layer 382 may include silicon oxide. In some aspects, the structure 700G may correspond to the resulting structure of stage 475 in FIG. 4B.

As shown in FIG. 7H, a structure 700H is formed based on the structure 700G by removing the sacrificial structures 722, 723, 724, and 728, and then performing an epi stop punch through process to remove a portion of the epitaxial stop layer 362 under the S/D structures 122, 123, and 124 and exposed after the removal of the sacrificial structures 722, 723, 724, and 728. As shown in FIG. 7H, after the sacrificial removal process and the epi stop punch through process, backside openings 732a-732d are defined. In some aspects, the backside openings 732a-732d may correspond to the positions where the backside conductive structures 332, 333, 334, and 338 will be formed. In some aspects, the structure 700H may correspond to the resulting structure of stage 480 in FIG. 4B.

As shown in FIG. 7I, a structure 700I is formed based on the structure 700H by filling the backside openings 732a-732d with a conductive or metallic material to form the backside conductive structures 332, 333, 334, and 338. In some aspects, the conductive or metallic material may include tungsten, cobalt, molybdenum, or a combination thereof. In some aspects, the structure 700I may correspond to the resulting structure of stage 482 in FIG. 4B. In some aspects, the backside dielectric layer 382 and the conductive structures disposed therein may be referred to as a first backside metallization layer.

As shown in FIG. 7J, a structure 700J may be formed based on the structure 700I by forming a second backside metallization layer that includes a backside dielectric layer 384 and the conductive structures disposed therein. As shown in FIG. 7J, the backside dielectric layer 384 is formed and patterned to define openings, and the via structures 393 and 394 and the backside conductive structure 342 may be formed based on the openings. In some aspects, the via structures 393 and 394 are electrically connected to the backside conductive structures 332 and 334, respectively. In some aspects, the backside conductive structure 342 may extend along the second direction (e.g., the x direction) and in contact with the backside conductive structures 332 and 338. In some aspects, the structure 700H may correspond to the resulting structure of stage 490 in FIG. 4B.

As shown in FIG. 7K, a structure 700K may be formed based on the structure 700J by forming a third backside metallization layer that includes a backside dielectric layer 386 and the conductive structures disposed therein. As shown in FIG. 7K, the backside dielectric layer 386 is formed and patterned to define openings, and the backside conductive structure 242 may be formed based on the openings. In some aspects, the via structures 393 and 394 electrically connect the backside conductive structures 332 and 334 to the backside conductive structure 242. Also, the backside conductive structure 332 may be electrically isolated from the backside conductive structure 242 by the backside dielectric layer 384. In some aspects, the structure 700K may correspond to the resulting structure of stage 495 in FIG. 4B. In some aspects, the structure 700K may correspond to the structure 300 shown in FIGS. 3D and 3E.

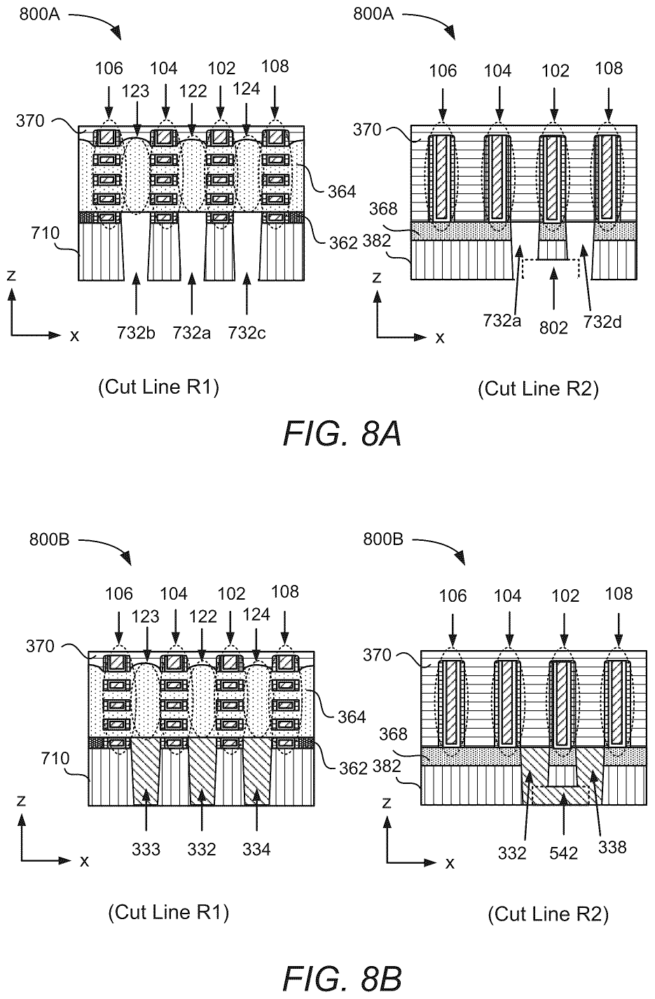

FIGS. 8A-8B, together with FIGS. 7A-7H, illustrate structures at various stages of manufacturing a semiconductor structure 500 of FIGS. 5A-5B, according to aspects of the disclosure. Each one of FIGS. 8A-8B includes a cross-sectional view (denoted “Cut Line R1”) on the left that is taken along a cut line corresponding to the cut line R1 in FIG. 5A; and a cross-sectional view (denoted “Cut Line R2”) on the right that is taken along a cut line corresponding to the cut line R2 in FIG. 5A. The semiconductor structure 500 may be manufactured based on the processes corresponding to FIGS. 7A-7H, and then followed by the processes as illustrated with reference to FIGS. 8A and 8B. The elements illustrated in FIGS. 8A and 8B that are the same or similar to those of FIGS. 5A and 5B and 7A-7H are given the same reference numbers, and the detailed description thereof may be omitted.

As shown in FIG. 8A, a structure 800A may be formed based on the structure 700H by performing a jumper patterning process to modify the openings 732a and 732b by adding a jumper opening portion 802. The jumper opening portion 802 may correspond to the position where a backside conductive structure 542 will be integrally formed with the backside conductive structures 332 and 338. In some aspects, the structure 800A may correspond to the resulting structure of stage 681 in FIG. 6B.

As shown in FIG. 8B, a structure 800B may be formed based on the structure 800B by filling the backside openings 732a-732d and 802 with a conductive or metallic material to form the backside conductive structures 332, 333, 334, 338, and 542. In some aspects, the conductive or metallic material may include tungsten, cobalt, molybdenum, or a combination thereof. In some aspects, the structure 800B may correspond to the resulting structure of stage 683 in FIG. 6B. In some aspects, the backside dielectric layer 382 and the conductive structures disposed therein may be referred to as a first backside metallization layer.

After FIG. 8B, one or more backside metallization layers may be formed, including a second backside metallization layer that includes conductive vias (e.g., the conductive via structures 393 and 394 as a result of stage 688 in FIG. 6B) and a third backside metallization layer that includes other conductive structures (e.g., the conductive structure 242 as a result of stage 495 in FIG. 6B). In some aspects, the resulting structure may correspond to the structure 500 shown in FIGS. 5A and 5B.

In some aspects, while the examples illustrated in FIGS. 3A-8B include backside conductive structures formed based on a self-aligned scheme by forming sacrificial structures from the front side, the backside conductive structures may be formed entirely from the back side. In some aspects, the processes corresponding to stages 418-422 may be omitted, and the processes corresponding to stage 480 may be modified to form the backside conductive structure openings from the back side without relying on the sacrificial structures formed from the front side.

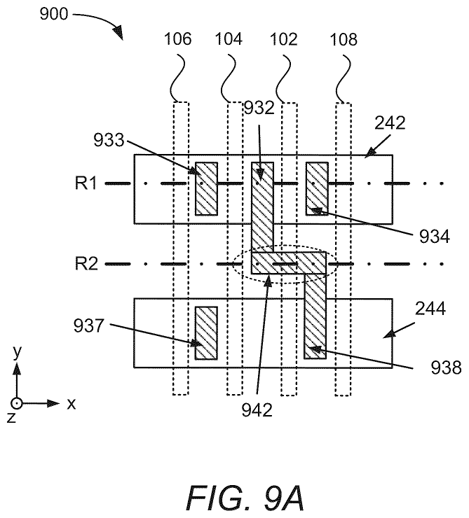

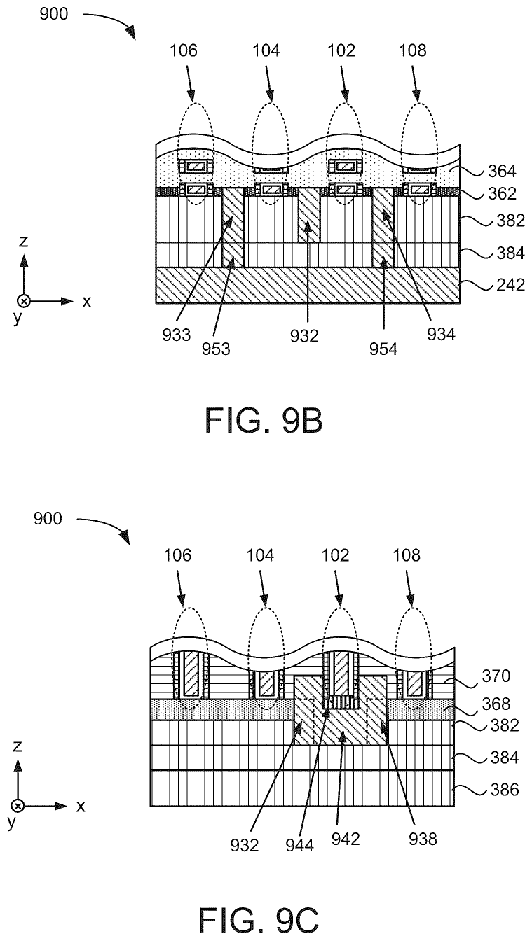

FIG. 9A is a top view of a portion of a semiconductor structure 900 of an IC device, according to aspects of the disclosure. In some aspects, the semiconductor structure 900 may be a variation of the semiconductor structure 300, and the portion of semiconductor structure 900 that are above the elements shown in FIG. 9A may correspond to the portion of semiconductor structure 300 depicted in FIG. 3A. In some aspects, FIG. 9A in combination of FIG. 3A merely show some elements of the semiconductor structure 900 for illustration purposes, and other elements above and/or below the elements shown in FIGS. 9A and 3A may be disposed but not shown in FIGS. 9A and 3A. The elements that are the same or similar to those in FIGS. 3A-3E are given the same reference numbers, and detailed description thereof may be omitted.

As shown in FIG. 9A, compared to the semiconductor structure 300 depicted in FIG. 3B, the semiconductor structure 900 includes backside conductive structures 932, 933, 934, 937, and 938 in place of the backside conductive structured 332, 333, 334, 337, and 338 in FIG. 3B; and a backside conductive structure 942 in place of the backside conductive structure 342 in FIG. 3B. In some aspects, instead of the backside conductive structured 332, 333, 334, 337, and 338 formed based on a self-aligned scheme, the backside conductive structures 932, 933, 934, 937, and 938 are formed based on patterning the corresponding backside dielectric layer from the back side of the semiconductor structure. In some aspects, a portion of the backside conductive structure 942 may be disposed within the same backside metallization layer in which the conductive structures 332 and 338 are at least partially disposed.

FIG. 9B is a cross-sectional view of a portion of the semiconductor structure 900 of FIG. 9A along a cut line R1, with details of the gate stacks 102, 104, 106, and 108 simplified, according to aspects of the disclosure. FIG. 9C is a cross-sectional view of a portion of the semiconductor structure 900 of FIG. 9A along a cut line R2, with details of the gate stacks 102, 104, 106, and 108 simplified, according to aspects of the disclosure.

As shown in FIG. 9B, the backside conductive structure 932 is in contact with the S/D structure 122; the backside conductive structure 933 is in contact with the S/D structure 123; and the backside conductive structure 934 is in contact with the S/D structure 124. In some aspects, the backside conductive structures 932, 933, and 934 are partially embedded in the backside dielectric layer 382. In some aspects, the backside dielectric layer 382 and the corresponding metallization structures disposed therein may be referred to as a first backside metallization layer under the S/D structures.

The semiconductor structure 900 further includes via structures 953 and 954 embedded in a backside dielectric layer 384 under the backside dielectric layer 382 and a backside conductive structure 242 embedded in a backside dielectric layer 386 (FIG. 9C) under the backside dielectric layer 384. In some aspects, the backside dielectric layer 384 and the corresponding metallization structures disposed therein may be referred to as a second backside metallization layer under the first backside metallization layer. In some aspects, the backside dielectric layer 386 and the corresponding metallization structures disposed therein may be referred to as a third backside metallization layer under the second backside metallization layer. The via structures 953 and 954 electrically connect the backside conductive structures 932 and 934 to the backside conductive structure 242, respectively. Also, the backside conductive structure 932 is electrically isolated from the backside conductive structure 242 by the backside dielectric layer 384.

As shown in FIG. 9C, the semiconductor structure 900 further includes the backside conductive structure 942 embedded in the backside dielectric layer 382 (e.g., in the first backside metallization layer) and may extend upward and partially in the front side dielectric layer 370. Also, a dielectric structure 944 is disposed under a bottom gate electrode portion of the gate stack 102 (in a connecting portion of the gate stack between the first gate structure and the second gate structure) and is configured to electrically isolate the backside conductive structure 942 from the bottom gate electrode portion of the connecting portion of the gate stack 102. In some aspects, the dielectric structure 944 may be formed based on area specific deposition (ASD) and may be referred to as an ASD structure. In some aspects, the backside conductive structures 932 and 938 may extend along the first direction (e.g., the y direction). In some aspects, the backside conductive structure 942 may extend along the second direction (e.g., the x direction) and in contact with the backside conductive structures 932 and 938. In some aspects, the backside conductive structure 942 may be integrally formed with the backside conductive structures 932 and 938.

Accordingly, as shown in FIGS. 9A-9C, the semiconductor structure 900 may include the backside conductive structure 932 in contact with the S/D structure 122 and disposed at least partially in the back portion of the semiconductor structure opposing the front portion; the backside conductive structure 938 in contact with the S/D structure 128 and disposed at least partially in the back portion of the semiconductor structure; and the backside conductive structure 942 disposed in the back portion of the semiconductor structure, extending along the second direction, and in contact with the backside conductive structure 932 and the backside conductive structure 938. In some aspects, the dielectric structure 944 may be disposed under a connecting portion of the gate stack between the first gate structure and second gate structure. In some aspects, the backside conductive structure 942 may be disposed at least partially under the connecting portion of the gate stack, and the dielectric structure 944 may be configured to electrically isolate the third backside conductive structure 942 from a bottom gate electrode portion of the connecting portion of the gate stack. In some aspects, the dielectric structure 944 may be in contact with the bottom gate electrode portion of the connecting portion of the gate stack. In some aspects, at least a portion of the backside conductive structure 942 may be above a lower surface of the gate stack and extends along an inner spacer of the connecting portion of the gate stack.

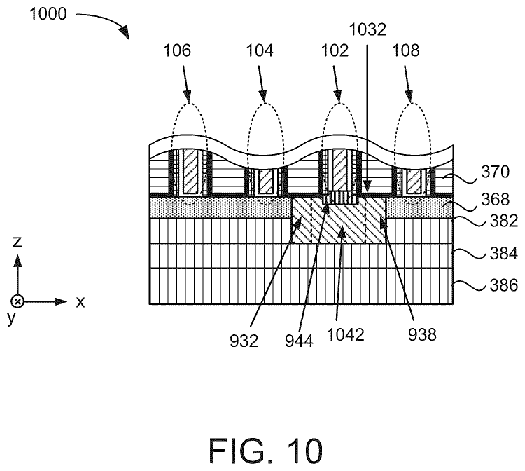

FIG. 10 is a cross-sectional view of a portion of the semiconductor structure 1000, according to aspects of the disclosure. In some aspects, the semiconductor structure 1000 may be a variation of the semiconductor structure 900.

As shown in FIG. 10, compared with the semiconductor structure 900, the semiconductor structure 1000 includes an etch stop layer 1032 between the front side dielectric layer 370 and the STI structure 368. As a result, the backside conductive structure 1042 that corresponds to the backside conductive structure 942 in FIGS. 9A-9B may not extend beyond the etch stop layer 1032 and may not enter the front side dielectric layer 370. As such, in some aspects, an entirety of the backside conductive structure 1042 may be below the connecting portion of the gate stack.

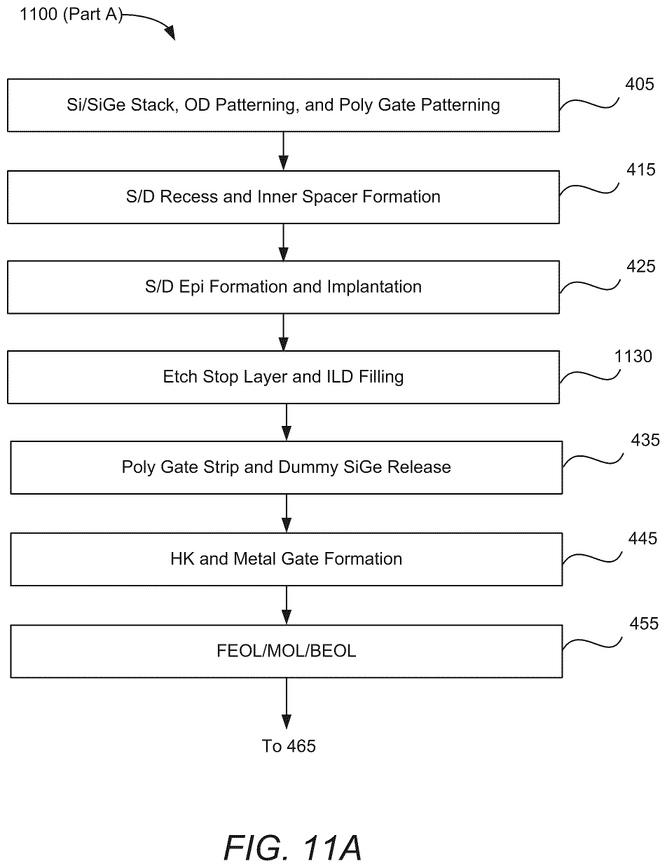

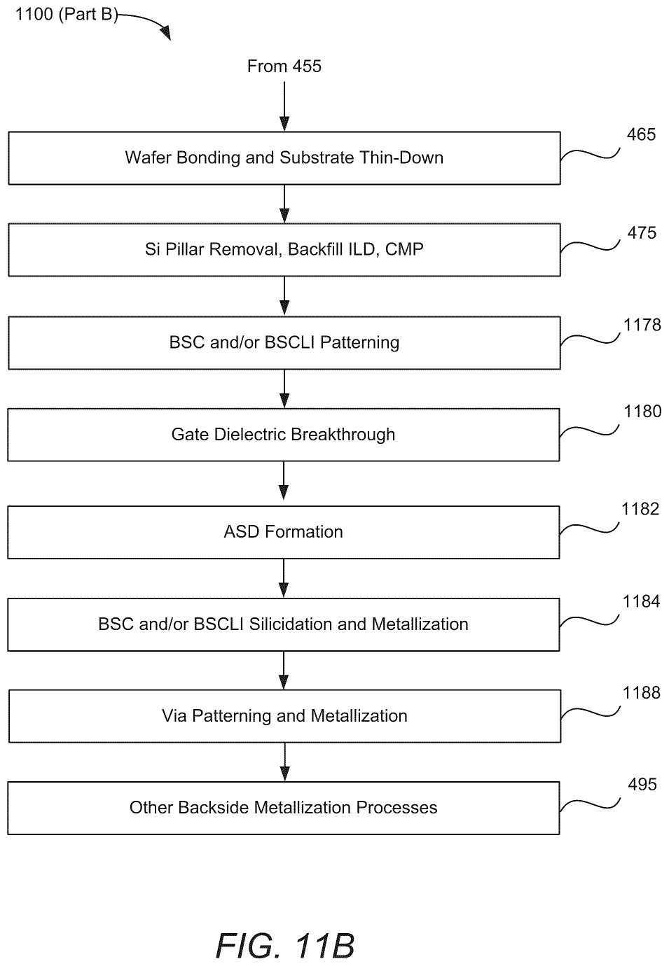

FIGS. 11A and 11B illustrate a manufacturing process 1100 for manufacturing a semiconductor structure (e.g., the semiconductor structure 900 in FIGS. 9A-9C or the semiconductor structure 1000 in FIG. 10), according to aspects of the disclosure. In some aspects, the processing stages shown in FIG. 11A (labeled as “Part A” of the manufacturing process 1100) may correspond to front-side processing of the semiconductor structure, as these stages may correspond to processes performed from a front side of a wafer on which the semiconductor structure is formed. In some aspects, the processing stages shown in FIG. 11B (labeled as “Part B” of the manufacturing process 1100) may correspond to back-side processing of the wafer, as these stages may correspond to processes performed from a back side of the wafer opposing the front side of the wafer.

In some aspects, the process 1100 may be a variation of the process 400 in FIGS. 4A-4B. The stages that are the same or similar to those in FIGS. 4A-4B are given the same reference numbers, and detailed description thereof may be omitted. In some aspects, the process may include stages 405, 415, 425, 435, 445, 455, 465, and 475 that are the same or similar to the corresponding counterparts illustrated with reference to FIGS. 4A-4B.

After stage 425, at stage 1130, an etch stop layer (e.g., the etch stop layer 1032) may be formed and then the front side dielectric layer 370 may be formed based on an ILD filling process. In some aspects, the etch stop layer formation part at stage 1130 may be performed for forming the semiconductor structure 1000. In some aspects, the etch stop layer formation part at stage 1130 may be omitted for forming the semiconductor structure 900.

After stage 475, at stage 1178, the openings for forming the backside conductive structures (e.g., the backside conductive structures 932, 933, 934, 937, and 938 as well as the backside conductive structure 942 or the backside conductive structure 1042) may be defined in the backside dielectric layer 382 and through corresponding portions of the epitaxial stop layer 362 and/or STI structure 368 based on a BSC and/or BSCLI patterning process.

At stage 1180, a gate dielectric breakthrough process is performed to further expose a bottom gate electrode portion of a gate stack at where the backside conductive structure 942 or the backside conductive structure 1042 is to be formed. In some aspects, the gate dielectric breakthrough process may extend the opening from stage 1178 further into the front side dielectric layer 370.

At stage 1182, a dielectric structure (e.g., the dielectric structure 944) may be formed under the bottom gate electrode portion of the gate stack and electrically isolating the bottom gate electrode portion from the subsequently formed backside conductive structures. In some aspects, the dielectric structure disposed at stage 1182 may be an ASD structure. In some aspects, an ASD process is performed at stage 1182 to selectively grow the ASD structure on the surface of the exposed bottom gate electrode portion. In some aspects, the surface of the exposed bottom gate electrode portion may include titanium nitride (TiN) or tungsten (W), and the ASD structure may include silicon oxide, hafnium oxide, zirconium oxide, silicon nitride, aluminum nitride, or any combination thereof.

At stage 1184, the backside opening from stage 1180 with the dielectric structure disposed at stage 1182 may be silicide and/or filled with a conductive or metallic material to form the backside conductive structures 932, 933, 934, 937, and 938 as well as the backside conductive structure 942 or the backside conductive structure 1042. In some aspects, the backside conductive structure 942 or the backside conductive structure 1042 may be integrally formed with the backside conductive structures 932 and 938.

At stage 1188, an additional backside dielectric layer (e.g., the backside dielectric layer 384) is formed and patterned to define the openings for forming the via structures in a patterning process, and the openings are filled with one or more conductive materials in a metallization process to form the via structures.

After stage 1188, at stage 495, other backside metallization processes may be performed to form additional metallization layers, including one or more power lines (e.g., the backside conductive structures 242 and 244) and/or one or more signal lines. In some aspects, one or more conductive pads may be formed, where a resulting integrated circuit device based on the semiconductor structure described herein may be attached to another integrated circuit device, an interposer, or a packaging substrate through the one or more conductive pads.

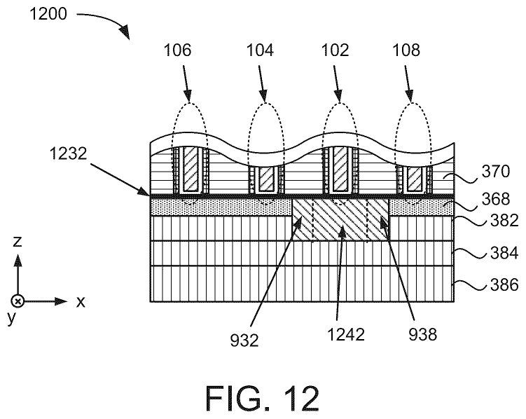

FIG. 12 is a cross-sectional view of a portion of the semiconductor structure 1200, according to aspects of the disclosure. In some aspects, the semiconductor structure 1200 may be another variation of the semiconductor structure 900.

As shown in FIG. 12, compared with the semiconductor structure 900, the semiconductor structure 1200 includes an etch stop layer 1232 under the connecting portion of the gate stack. As a result, the backside conductive structure 1242 that corresponds to the backside conductive structure 942 in FIGS. 9A-9B may not extend beyond the etch stop layer 1232 and may not enter the front side dielectric layer 370. Also, the dielectric structure 944 (e.g., an ASD structure) may be omitted, as the etch stop layer 1232 may be configured as a dielectric structure under the connecting portion of the gate stack to keep the backside conductive structure 1242 separated from the bottom gate electrode portion at the connecting portion of the gate stack.

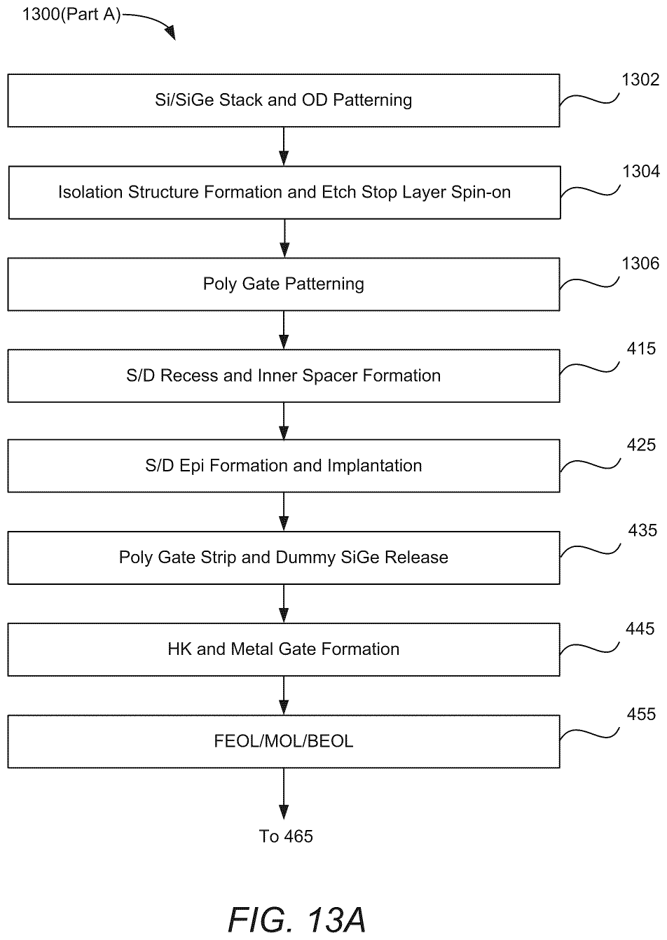

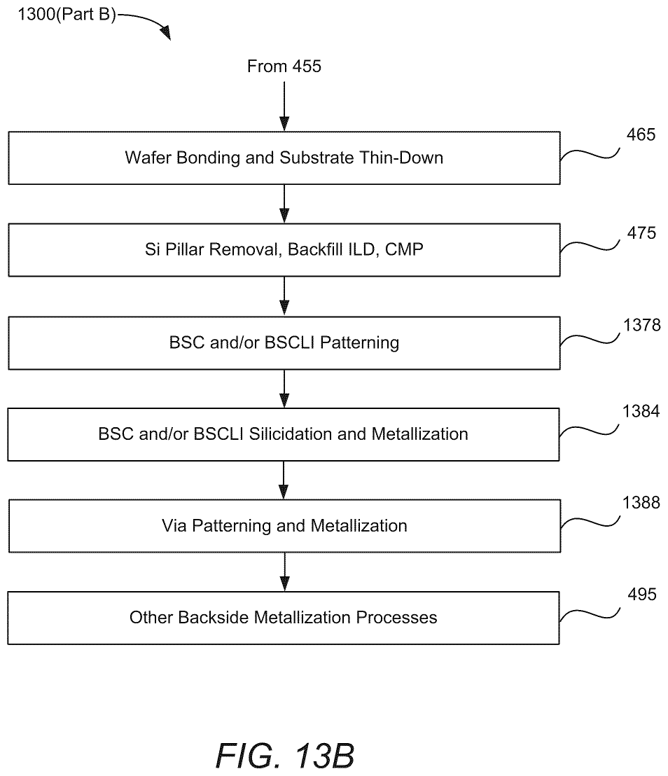

FIGS. 13A and 13B illustrate a manufacturing process 1300 for manufacturing a semiconductor structure (e.g., the semiconductor structure 1200 in FIG. 12), according to aspects of the disclosure. In some aspects, the processing stages shown in FIG. 13A (labeled as “Part A” of the manufacturing process 1300) may correspond to front-side processing of the semiconductor structure, as these stages may correspond to processes performed from a front side of a wafer on which the semiconductor structure is formed. In some aspects, the processing stages shown in FIG. 13B (labeled as “Part B” of the manufacturing process 1300) may correspond to back-side processing of the wafer, as these stages may correspond to processes performed from a back side of the wafer opposing the front side of the wafer.

In some aspects, the process 1300 may be a variation of the process 400 in FIGS. 4A-4B or a variation of the process 1100 in FIGS. 11A-11B. The stages that are the same or similar to those in FIGS. 11A-11B are given the same reference numbers, and detailed description thereof may be omitted. In some aspects, the process may include stages 415, 425, 435, 445, 455, 465, and 475 that are the same or similar to the corresponding counterparts illustrated with reference to FIGS. 4A-4B.

Prior to stage 415, at stage 1302, a multi-layer structure may be formed on a substrate of a wafer. In some aspects, the multi-layer structure may include layers of different silicon materials stacked one over another. In some aspects the multi-layer structure may include layers of silicon (Si) and silicon germanium (SiGe) stacked one over another as a Si/SiGe stack. Also, at stage 1302, an active area of the semiconductor structure may be defined based on an oxide diffusion (OD) pattern. In some aspects, an OD patterning process may be performed on the multi-layer structure (e.g., the Si/SiGe stack) to shape the multi-layer structure into a fin-like structure. In some aspects, stage 1302 may correspond to the first half of stage 405 in FIG. 4A.

At stage 1304, an isolation structure formation process is performed to form isolation structures (e.g., STI structures). An etch stop layer spin-on process is then performed to form an etch stop layer (e.g., the etch stop layer 1232) on the substrate and the STI structures.

At stage 1306, a layer of polysilicon material may be formed on the fin-like structure from stage 1302 and the etch stop layer from stage 1304, and a poly gate patterning process may be performed on the layer of polysilicon material to form a patterned polysilicon structure on the fin-like structure. In some aspects, stage 1302 may correspond to the second half of stage 405 in FIG. 4A. Afterwards, the process 1300 may proceed to stage 415.

Also, after stage 475, at stage 1378, the openings for forming the backside conductive structures (e.g., the backside conductive structures 932, 933, 934, 937, and 938 as well as the backside conductive structure 1242) may be defined in the backside dielectric layer 382 and through corresponding portions of the epitaxial stop layer 362 and/or STI structure 368 based on a BSC and/or BSCLI patterning process.

At stage 1384, the backside opening from stage 1378 may be silicide and/or filled with a conductive or metallic material to form the backside conductive structures 932, 933, 934, 937, and 938 as well as the backside conductive structure 1242. In some aspects, the backside conductive structure 1242 may be integrally formed with the backside conductive structures 932 and 938.

At stage 1388, an additional backside dielectric layer (e.g., the backside dielectric layer 384) is formed and patterned to define the openings for forming the via structures in a patterning process, and the openings are filled with one or more conductive materials in a metallization process to form the via structures.

After stage 1388, at stage 495, other backside metallization processes may be performed to form additional metallization layers, including one or more power lines (e.g., the backside conductive structures 242 and 244) and/or one or more signal lines. In some aspects, one or more conductive pads may be formed, where a resulting integrated circuit device based on the semiconductor structure described herein may be attached to another integrated circuit device, an interposer, or a packaging substrate through the one or more conductive pads.

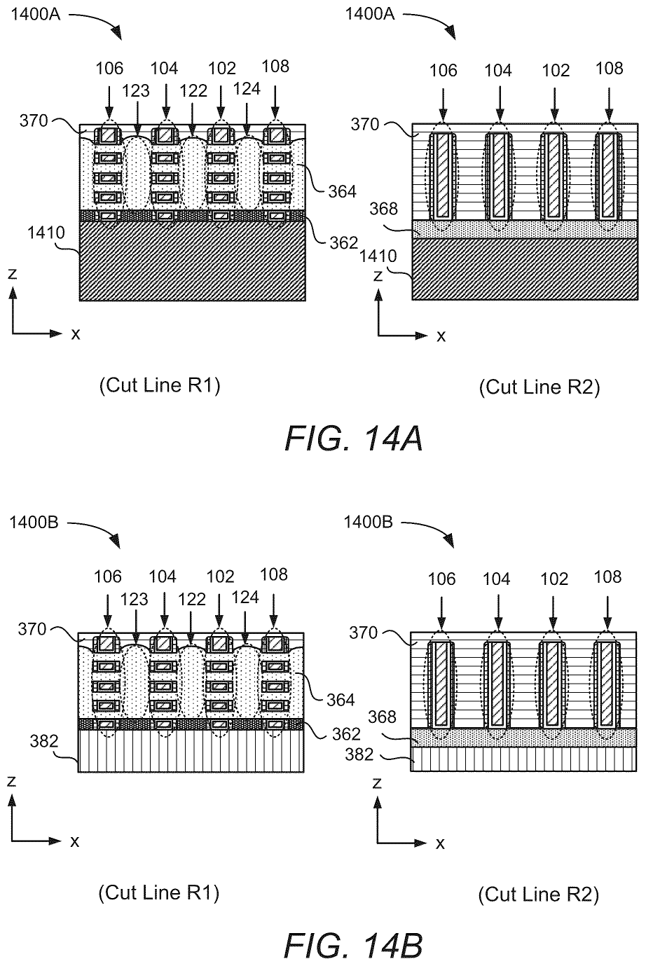

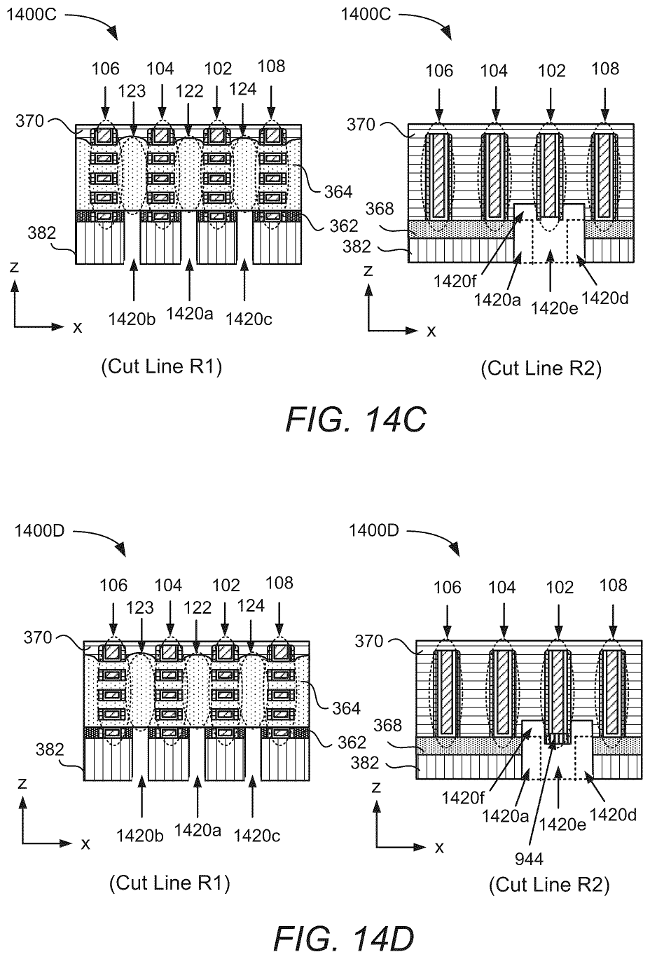

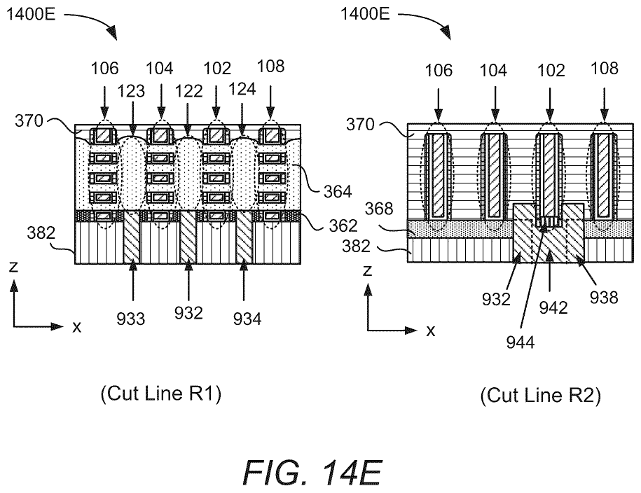

FIGS. 14A-14E illustrate structures at various stages of manufacturing a semiconductor structure 900 of FIGS. 9A-9C, according to aspects of the disclosure. Each one of FIGS. 14A-14E includes a cross-sectional view (denoted “Cut Line R1”) on the left that is taken along a cut line corresponding to the cut line R1 in FIG. 9A; and a cross-sectional view (denoted “Cut Line R2”) on the right that is taken along a cut line corresponding to the cut line R2 in FIG. 9A. The elements illustrated in FIGS. 14A-14E that are the same or similar to those of FIGS. 9A-9C are given the same reference numbers, and the detailed description thereof may be omitted.

As shown in FIG. 14A, a structure 1400A is provided. The structure 1400A may be prepared based on stages 405-445 without stage 1130 as shown in FIG. 11A. The structure 1400A may include four gate stacks 102, 104, 106, and 108 on a substrate 1410, an epitaxial stop layer 362 disposed on the substrate 1410, an epitaxial layer 364 disposed on the epitaxial stop layer 362, and a front side dielectric layer 370 (e.g., a front side ILD layer) on the gate stacks 102, 104, 106, and 108 and the epitaxial layer 364.

Also, the structure 1400A includes S/D structures 122, 123, and 124 defined based on the epitaxial layer 364 between corresponding gate stack pairs 102 and 104, 104 and 106, and 102 and 108. An STI structure 368 may be embedded in the substrate 1410 in the area outside the active areas that correspond to the position of the S/D structures and channel structures of the resulting transistors. Compared with the structure 700F in FIG. 7F, the structure 1400A does not include the sacrificial structures 722, 723, 724, and 728.

As shown in FIG. 14B, a structure 1400B is formed based on the structure 1400A. In some aspects, one or more of FEOL process, MOL process, or BEOL process may be performed on the structure 1400A from the front side, and the wafer on which the semiconductor structure 1400A is formed may be bonded to a carrier and flipped for various further processes from the back side. In some aspects, a substrate thin-down process may be performed from the back side to remove at least a portion of the substrate 1410, and the rest of the substrate 1410 may be further removed during a silicon pillar removal process. Afterwards, the backside dielectric layer 382 may be formed. In some aspects, the backside dielectric layer 382 may include silicon oxide. In some aspects, the structure 1400B may correspond to the resulting structure of stage 475 in FIG. 11B.

As shown in FIG. 14C, a structure 1400C is formed based on the structure 1400B by performing a BSC and/or BSCLI patterning process to define the openings 1420a, 1420b, 1420c, 1420d, and 1420e for forming the backside conductive structures (e.g., the backside conductive structures 932, 933, 934, 937, and 938 as well as the backside conductive structure 942), and followed by a gate dielectric breakthrough process to define an expanded opening portion 1420f to further expose a bottom gate electrode portion of a gate stack at where the backside conductive structure 942 is to be formed. In some aspects, the structure 1400C may correspond to the resulting structure of stage 1180 in FIG. 11B.

As shown in FIG. 14D, a structure 1400D is formed based on the structure 1400C by forming a dielectric structure 944 under the bottom gate electrode portion of the gate stack and electrically isolating the bottom gate electrode portion from the subsequently formed backside conductive structures. In some aspects, an ASD process is performed to selectively grow an ASD structure as the dielectric structure 944 on the surface of the exposed bottom gate electrode portion. In some aspects, the structure 1400D may correspond to the resulting structure of stage 1182 in FIG. 11B.

As shown in FIG. 14E, a structure 1400E is formed based on the structure 1400D by filling the backside openings 1420a-1420f (with the dielectric structure 944 formed therein) the with a conductive or metallic material to form the backside conductive structures 932, 933, 934, 938, and 942. In some aspects, the backside conductive structure 942 may extend along the second direction (e.g., the x direction) and in contact with the backside conductive structures 932 and 938. In some aspects, the conductive or metallic material may include tungsten, cobalt, molybdenum, or a combination thereof. In some aspects, the structure 1400E may correspond to the resulting structure of stage 1184 in FIG. 11B. In some aspects, the backside dielectric layer 382 and the conductive structures disposed therein may be referred to as a first backside metallization layer.

After FIG. 14E, one or more backside metallization layers may be formed, including a second backside metallization layer that includes conductive vias (e.g., the conductive vias 953 and 954 as a result of stage 1188 in FIG. 11B) and a third backside metallization layer that includes other conductive structures (e.g., the conductive structure 242 as a result of stage 495 in FIG. 11B). In some aspects, the resulting structure may correspond to the structure 900 shown in FIGS. 9A-9C.

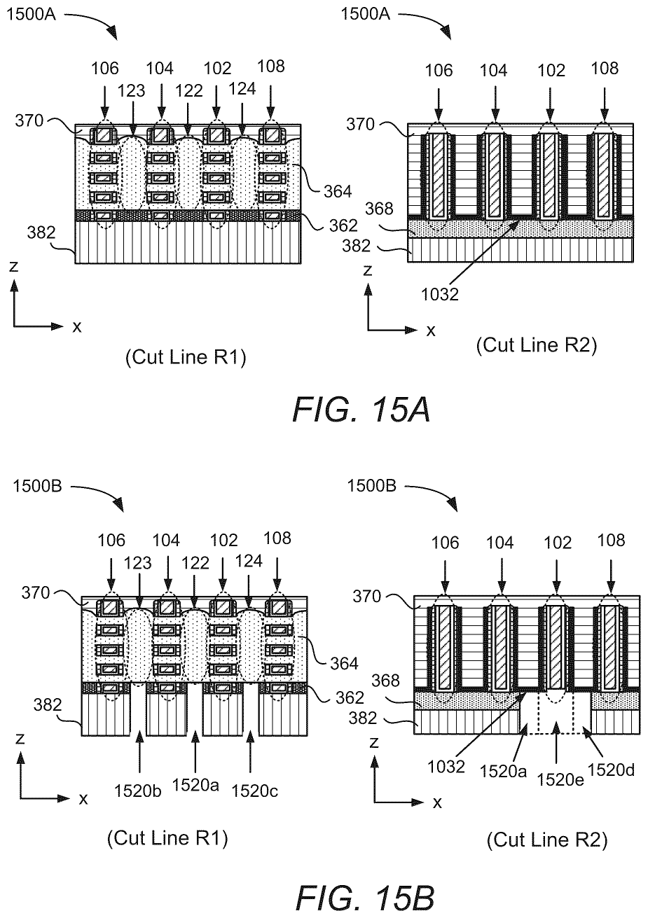

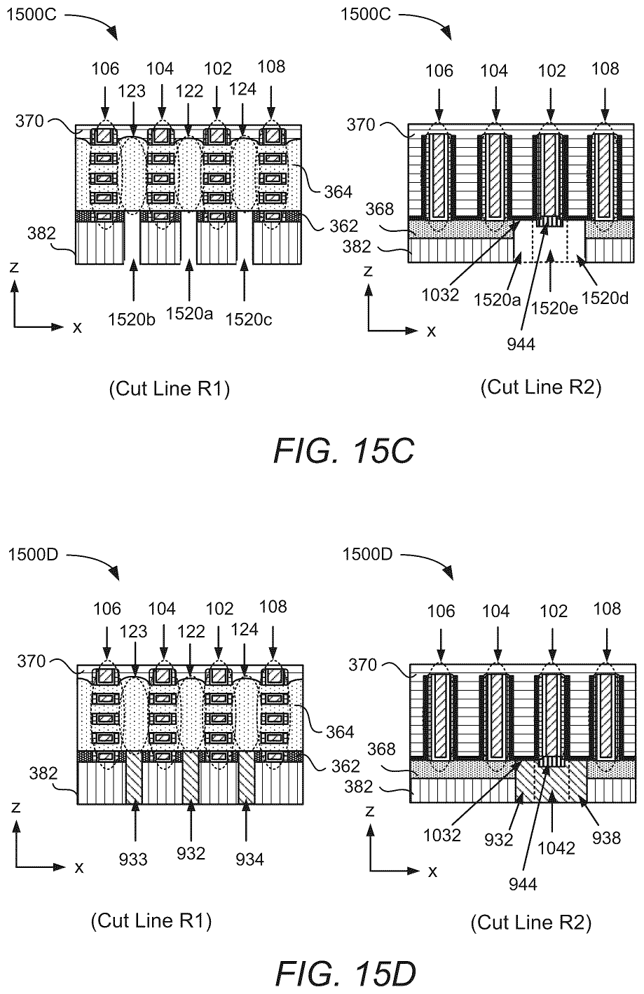

FIGS. 15A-15D illustrate structures at various stages of manufacturing a semiconductor structure 1000 of FIG. 10, which is a variation of the semiconductor structure 900 of FIG. 9, according to aspects of the disclosure. Each one of FIGS. 15A-15D includes a cross-sectional view (denoted “Cut Line R1”) on the left that is taken along a cut line corresponding to the cut line R1 in FIG. 9A; and a cross-sectional view (denoted “Cut Line R2”) on the right that is taken along a cut line corresponding to the cut line R2 in FIG. 9A. The elements illustrated in FIGS. 15A-15D that are the same or similar to those of FIGS. 9A-9C and 10 are given the same reference numbers, and the detailed description thereof may be omitted.

As shown in FIG. 15A, a structure 1500A is provided. Compared with the structure 1400B in FIG. 14B, the structure 1500A further includes an etch stop layer 1032 between the front side dielectric layer 370 and the STI structure 368 and along the sides of the gate stacks 102, 104, 106, and 108 outside of the region where the channel structures and S/D structures may be formed.

As shown in FIG. 15B, a structure 1500B is formed based on the structure 1500A by performing a BSC and/or BSCLI patterning process to define the openings 1520a, 1520b, 1520c, 1520d, and 1520e for forming the backside conductive structures (e.g., the backside conductive structures 932, 933, 934, 937, and 938 as well as the backside conductive structure 1042), and followed by a gate dielectric breakthrough process to expand the opening portion 1520e to further expose a bottom gate electrode portion of a gate stack at where the backside conductive structure 1042 is to be formed. In some aspects, the structure 1500B may correspond to the resulting structure of stage 1180 in FIG. 11B.

As shown in FIG. 15C, a structure 1500C is formed based on the structure 1500B by forming a dielectric structure 944 under the bottom gate electrode portion of the gate stack and electrically isolating the bottom gate electrode portion from the subsequently formed backside conductive structures. In some aspects, an ASD process is performed to selectively grow an ASD structure as the dielectric structure 944 on the surface of the exposed bottom gate electrode portion. In some aspects, the structure 1500C may correspond to the resulting structure of stage 1182 in FIG. 11B.

As shown in FIG. 15D, a structure 1500D is formed based on the structure 1500C by filling the backside openings 1520a-1520e (with the dielectric structure 944 formed therein) the with a conductive or metallic material to form the backside conductive structures 932, 933, 934, 938, and 1042. In some aspects, the backside conductive structure 1042 may extend along the second direction (e.g., the x direction) and in contact with the backside conductive structures 932 and 938. In some aspects, the conductive or metallic material may include tungsten, cobalt, molybdenum, or a combination thereof. In some aspects, the structure 1500D may correspond to the resulting structure of stage 1184 in FIG. 11B. In some aspects, the backside dielectric layer 382 and the conductive structures disposed therein may be referred to as a first backside metallization layer.

In some aspects, as the etch stop layer 1032 stop the openings from being extended into the front side dielectric layer 370, the backside conductive structure 1042 may not extend beyond the etch stop layer 1032 and may not enter the front side dielectric layer 370.

After FIG. 15D, one or more backside metallization layers may be formed, including a second backside metallization layer that includes conductive vias (e.g., the conductive vias 953 and 954 as a result of stage 1188 in FIG. 11B) and a third backside metallization layer that includes other conductive structures (e.g., the conductive structure 242 as a result of stage 495 in FIG. 11B). In some aspects, the resulting structure may correspond to the structure 1000 shown in FIG. 10.

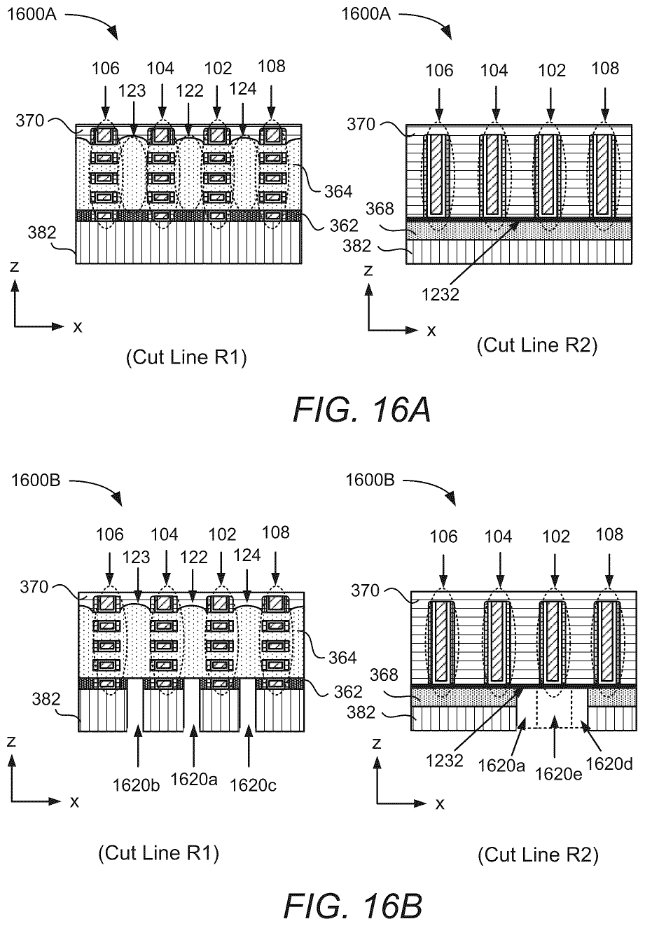

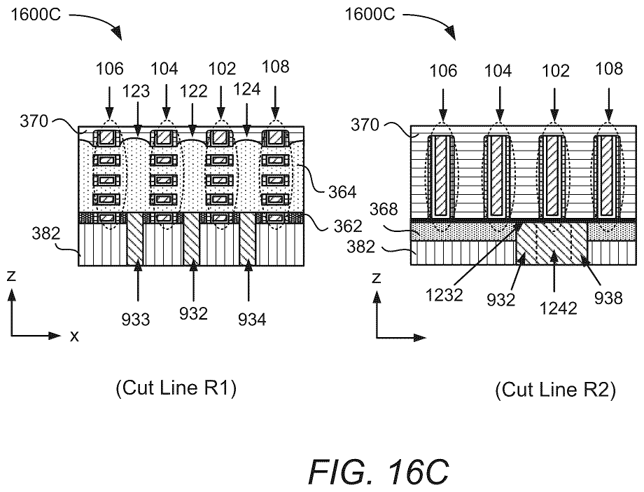

FIGS. 16A-16C illustrate structures at various stages of manufacturing a semiconductor structure 1200 of FIG. 12, which is another variation of the semiconductor structure 900 of FIG. 9, according to aspects of the disclosure. Each one of FIGS. 16A-16C includes a cross-sectional view (denoted “Cut Line R1”) on the left that is taken along a cut line corresponding to the cut line R1 in FIG. 9A; and a cross-sectional view (denoted “Cut Line R2”) on the right that is taken along a cut line corresponding to the cut line R2 in FIG. 9A. The elements illustrated in FIGS. 16A-16C that are the same or similar to those of FIGS. 9A-9C and 12 are given the same reference numbers, and the detailed description thereof may be omitted.

As shown in FIG. 16A, a structure 1600A is provided. Compared with the structure 1400B in FIG. 14B, the structure 1600A further includes an etch stop layer 1232 between the front side dielectric layer 370 and the STI structure 368 and under the gate stacks 102, 104, 106, and 108 outside of the region where the channel structures and S/D structures may be formed.

As shown in FIG. 16B, a structure 1600B is formed based on the structure 1600A by performing a BSC and/or BSCLI patterning process to define the openings 1620a, 1620b, 1620c, 1620d, and 1620e for forming the backside conductive structures (e.g., the backside conductive structures 932, 933, 934, 937, and 938 as well as the backside conductive structure 1242). In some aspects, the structure 1600B may correspond to the resulting structure of stage 1378 in FIG. 13B.

As shown in FIG. 16C, a structure 1600C is formed based on the structure 1600B by filling the backside openings 1620a-1620e with a conductive or metallic material to form the backside conductive structures 932, 933, 934, 938, and 1242. In some aspects, the backside conductive structure 1242 may extend along the second direction (e.g., the x direction) and in contact with the backside conductive structures 932 and 938. In some aspects, the conductive or metallic material may include tungsten, cobalt, molybdenum, or a combination thereof. In some aspects, the structure 1600C may correspond to the resulting structure of stage 1384 in FIG. 13B. In some aspects, the backside dielectric layer 382 and the conductive structures disposed therein may be referred to as a first backside metallization layer.

In some aspects, as the etch stop layer 1232 stop the openings from being extended into the front side dielectric layer 370, the backside conductive structure 1042 may not extend beyond the etch stop layer 1032 and may not enter the front side dielectric layer 370. Also, the dielectric structure 944 may be omitted.

After FIG. 16C, one or more backside metallization layers may be formed, including a second backside metallization layer that includes conductive vias (e.g., the conductive vias 953 and 954 as a result of stage 1388 in FIG. 13B) and a third backside metallization layer that includes other conductive structures (e.g., the conductive structure 242 as a result of stage 495 in FIG. 13B). In some aspects, the resulting structure may correspond to the structure 1200 shown in FIG. 12.

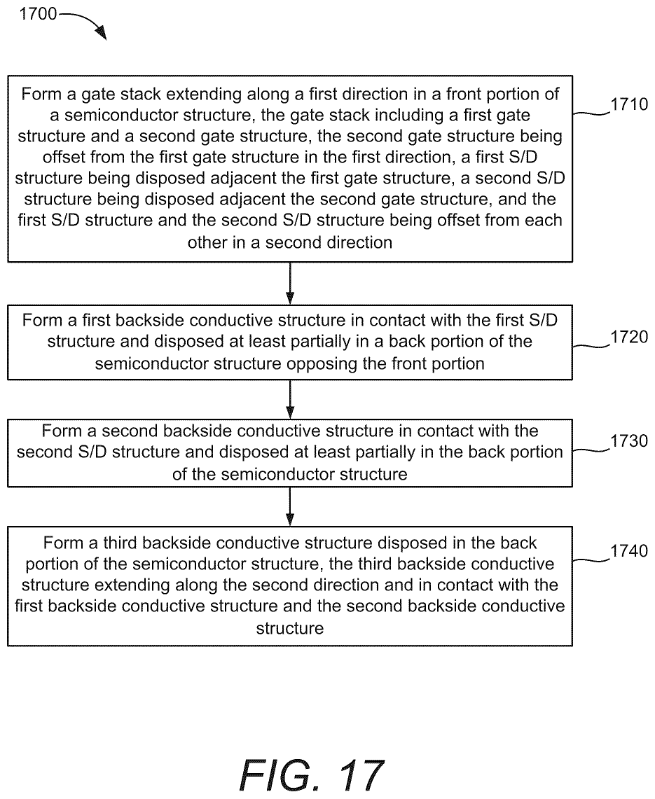

FIG. 17 illustrates a method 1700 for manufacturing a semiconductor structure (such as the semiconductor structure examples depicted in FIGS. 3A-3E, 5A-5B, 9A-9C, 10, and 12), according to aspects of the disclosure.

At operation 1710, a gate stack (e.g., the gate stack 102) is formed, where the gate stack extends along a first direction (e.g., the y direction) in a front portion of a semiconductor structure. In some aspects, the gate stack may include a first gate structure and a second gate structure, and the second gate structure being offset from the first gate structure in the first direction. In some aspects, a first S/D structure (e.g., the S/D structure 122) may be disposed adjacent the first gate structure, a second S/D structure (e.g., the S/D structure 128) may be disposed adjacent the second gate structure, and the first S/D structure and the second S/D structure being offset from each other in a second direction (e.g., the x direction). In some aspects, the gate stack may be formed based on stages 405-445 in FIG. 4A, 6A, 11A, or 13A, and the resulting structure may correspond to the structure in FIG. 7G, 14B, 15A, or 16A.

At operation 1720, a first backside conductive structure (e.g., the backside conductive structure 332 or 932) may be formed. The first backside conductive structure may be in contact with the first S/D structure and disposed at least partially in a back portion of the semiconductor structure opposing the front portion.

At operation 1730, a second backside conductive structure (e.g., the backside conductive structure 338 or 938) may be formed. The second backside conductive structure may be in contact with the second S/D structure and disposed at least partially in the back portion of the semiconductor structure.

At operation 1740, a third backside conductive structure (e.g., the backside conductive structure 342, 542, 942, 1042, or 1242) may be formed. The third backside conductive structure may be disposed in the back portion of the semiconductor structure. In some aspects, the third backside conductive structure may extend along the second direction and be in contact with the first backside conductive structure and the second backside conductive structure.

In some aspects, the first backside conductive structure and the second backside conductive structure may be formed within a first backside metallization layer under the first S/D structure and the second S/D structure, and the third backside conductive structure may be formed within a second backside metallization layer under the first backside metallization layer. In some aspects, the method 1700 may further include forming a fourth backside conductive structure (e.g., the via structure 393, 394, 953, and/or 954) within the second backside metallization layer, and forming a metallization structure (e.g., the backside conductive structure 242 and/or 244) disposed within a third backside metallization layer under the second backside metallization layer, the fourth backside conductive structure connecting the metallization structure to another backside conductive structure in the first backside metallization layer.

In some aspects, the method 1700 may further include forming a dielectric structure under a connecting portion of the gate stack between the first gate structure and second gate structure. In some aspects, the third backside conductive structure may be formed at least partially under the connecting portion of the gate stack, and the dielectric structure may be configured to electrically isolate the third backside conductive structure from a bottom gate electrode portion of the connecting portion of the gate stack.

In some aspects, the formation of the dielectric structure may include removing a portion of a gate dielectric portion of the connecting portion of the gate stack to expose the bottom gate electrode portion of the connecting portion of the gate stack; and performing an area selective deposition process to form the dielectric structure. In some aspects, the formation of the third backside conductive structure may include removing a portion of a front side interlayer dielectric layer adjacent an inner spacer of the connecting portion of the gate stack to define an opening. In some aspects, the third backside conductive structure is formed in the opening such that at least a portion of the third backside conductive structure is above a lower surface of the gate stack and extends along the inner spacer of the connecting portion of the gate stack.

In some aspects, the resulting semiconductor structure based on the method 1700 may correspond to the semiconductor structure 300 shown in FIGS. 3A-3E, and the semiconductor structure 300 may include the backside conductive structure 332 in contact with the S/D structure 122 and disposed at least partially in the back portion of the semiconductor structure opposing the front portion; the backside conductive structure 338 in contact with the S/D structure 128 and disposed at least partially in the back portion of the semiconductor structure; and the backside conductive structure 342 disposed in the back portion of the semiconductor structure, extending along the second direction, and in contact with the backside conductive structure 332 and the backside conductive structure 338. In some aspects, the backside conductive structure 332 and the backside conductive structure 338 may be disposed within a first backside metallization layer under the S/D structure 122 and the S/D structure 128, and the backside conductive structure 342 may be disposed within a second backside metallization layer under the first backside metallization layer. In some aspects, the backside conductive structure (e.g., the via structures 393 and 394) may be disposed within the second backside metallization layer. In some aspects, a metallization structure (e.g., the backside conductive structure 242 or 244) may be disposed within a third backside metallization layer under the second backside metallization layer. In some aspects, one or more via structures may be configured to connect the metallization structure to another backside conductive structure in the first backside metallization layer.

In some aspects, the resulting semiconductor structure based on the method 1700 may correspond to the semiconductor structure 500 shown in FIGS. 5A-5B, and the semiconductor structure 500 may include the backside conductive structure 332 in contact with the S/D structure 122 and disposed at least partially in the back portion of the semiconductor structure opposing the front portion; the backside conductive structure 338 in contact with the S/D structure 128 and disposed at least partially in the back portion of the semiconductor structure; and the backside conductive structure 542 disposed in the back portion of the semiconductor structure, extending along the second direction, and in contact with the backside conductive structure 332 and the backside conductive structure 338. In some aspects, the backside conductive structure 332 and the backside conductive structure 338 may be disposed within a first backside metallization layer under the S/D structure 122 and the S/D structure 128, and the backside conductive structure 542 may be disposed within a lower portion of the first backside metallization layer. In some aspects, the backside conductive structure (e.g., the via structures 393 and 394) may be disposed within the second backside metallization layer. In some aspects, a metallization structure (e.g., the backside conductive structure 242 or 244) may be disposed within a third backside metallization layer under the second backside metallization layer. In some aspects, one or more via structures may be configured to connect the metallization structure to another backside conductive structure in the first backside metallization layer.

In some aspects, the resulting semiconductor structure based on the method 1700 may correspond to the semiconductor structure 900 shown in FIGS. 9A-9C, and the semiconductor structure 900 may include the backside conductive structure 932 in contact with the S/D structure 122 and disposed at least partially in the back portion of the semiconductor structure opposing the front portion; the backside conductive structure 938 in contact with the S/D structure 128 and disposed at least partially in the back portion of the semiconductor structure; and the backside conductive structure 942 disposed in the back portion of the semiconductor structure, extending along the second direction, and in contact with the backside conductive structure 932 and the backside conductive structure 938. In some aspects, the dielectric structure 944 may be disposed under a connecting portion of the gate stack between the first gate structure and second gate structure. In some aspects, the backside conductive structure 942 may be disposed at least partially under the connecting portion of the gate stack, and the dielectric structure 944 may be configured to electrically isolate the third backside conductive structure 942 from a bottom gate electrode portion of the connecting portion of the gate stack. In some aspects, the dielectric structure 944 may be in contact with the bottom gate electrode portion of the connecting portion of the gate stack. In some aspects, at least a portion of the backside conductive structure 942 may be above a lower surface of the gate stack and extends along an inner spacer of the connecting portion of the gate stack.

In some aspects, the resulting semiconductor structure based on the method 1700 may correspond to the semiconductor structure 1000 shown in FIG. 10, and an entirety of the backside conductive structure 1042 of the semiconductor structure 1000 may be below the connecting portion of the gate stack. In some aspects, the resulting semiconductor structure based on the method 1700 may correspond to the semiconductor structure 1200 shown in FIG. 12, and the semiconductor structure 1200 may include an etch stop layer 1232 configured as a dielectric structure under the connecting portion of the gate stack to keep the backside conductive structure 1242 separated from the bottom gate electrode portion at the connecting portion of the gate stack.

A technical advantage of the method 1700 is the formation of the backside conductive structures (e.g., BSCs and BSCLIs) that are configured to extend along two different direction (i.e., backside bi-directional interconnects) for interconnections formed at the back portion of the semiconductor structure of an integrated circuit device, in order to provide additional routing capability or capacity for manufacturing the integrated circuit device. As a result, an IC device may be manufactured based on more compact standard cells and thus improve the area scaling thereof.

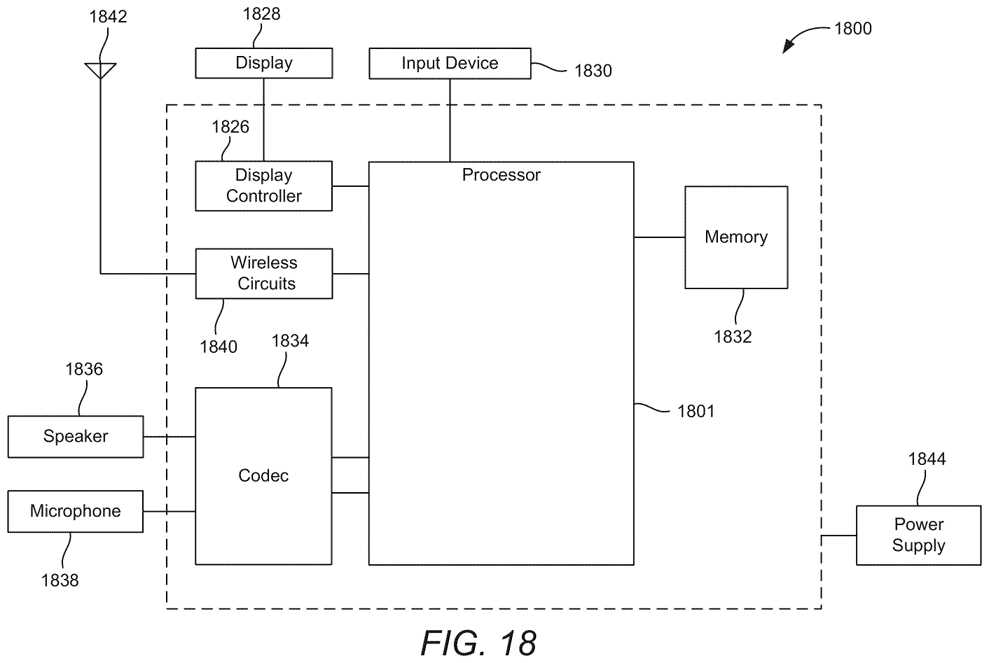

FIG. 18 illustrates a mobile device 1800, according to aspects of the disclosure. In some aspects, the mobile device 1800 may be implemented by including one or more IC devices manufactured based on the examples described in this disclosure.

In some aspects, mobile device 1800 may be configured as a wireless communication device. As shown, mobile device 1800 includes processor 1801. Processor 1801 may be communicatively coupled to memory 1832 over a link, which may be a die-to-die or chip-to-chip link. Mobile device 1800 also includes display 1828 and display controller 1826, with display controller 1826 coupled to processor 1801 and to display 1828. The mobile device 1800 may include input device 1830 (e.g., physical, or virtual keyboard), power supply 1844 (e.g., battery), speaker 1836, microphone 1838, and wireless antenna 1842. In some aspects, the power supply 1844 may directly or indirectly provide the supply voltage for operating some or all of the components of the mobile device 1800.

In some aspects, FIG. 18 may include coder/decoder (CODEC) 1834 (e.g., an audio and/or voice CODEC) coupled to processor 1801; speaker 1836 and microphone 1838 coupled to CODEC 1834; and wireless circuits 1840 (which may include a modem, RF circuitry, filters, etc.) coupled to wireless antenna 1842 and to processor 1801.

In some aspects, one or more of processor 1801, display controller 1826, memory 1832, CODEC 1834, and wireless circuits 1840 may include one or more IC devices including semiconductor structures manufactured according to the examples described in this disclosure.

It should be noted that although FIG. 18 depicts a mobile device 1800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

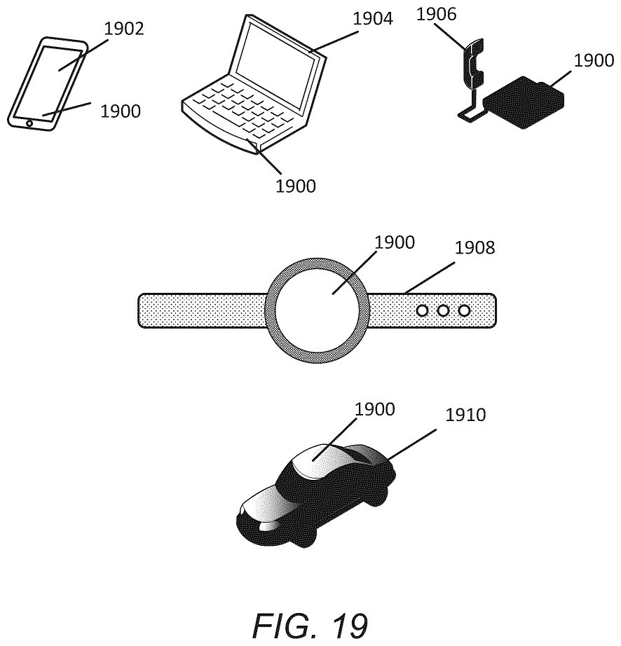

FIG. 19 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1902, a laptop computer device 1904, a fixed location terminal device 1906, a wearable device 1908, or automotive vehicle 1910 may include a semiconductor device 1900 (e.g., a semiconductor device including semiconductor structure 100, 200, 500, or 600) as described herein. The devices 1902, 1904, 1906 and 1908 and the vehicle 1910 illustrated in FIG. 19 are merely exemplary. Other apparatuses or devices may also feature the semiconductor device 1900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1 through 19 may be rearranged and/or combined into a single component, process, feature, or function or incorporated in several components, processes, or functions. Additional elements, components, processes, and/or functions may also be added without departing from the disclosure. In some implementations, FIGS. 1 through 19 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (PoP) device, and the like.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. UEs can be embodied by any of a number of types of devices including but not limited to printed circuit (PC) cards, compact flash devices, external or internal modems, wireless or wireline phones, smartphones, tablets, consumer tracking devices, asset tags, and so on.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth® (BT), Bluetooth® Low Energy (BLE), IEEE 802.11 (WiFi), and IEEE 802.15.4 (Zigbee®/Thread) or other protocols that may be used in a wireless communications network or a data communications network.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A semiconductor structure, comprising: a gate stack extending along a first direction in a front portion of the semiconductor structure, the gate stack including a first gate structure and a second gate structure offset from each other in the first direction; a first source/drain (S/D) structure adjacent the first gate structure; a second S/D structure adjacent the second gate structure, the second S/D structure being offset from the first S/D structure in a second direction; a first backside conductive structure in contact with the first S/D structure and disposed at least partially in a back portion of the semiconductor structure opposing the front portion; a second backside conductive structure in contact with the second S/D structure and disposed at least partially in the back portion of the semiconductor structure; and a third backside conductive structure disposed in the back portion of the semiconductor structure, the third backside conductive structure extending along the second direction and in contact with the first backside conductive structure and the second backside conductive structure.

Clause 2. The semiconductor structure of clause 1, wherein: the first backside conductive structure and the second backside conductive structure are disposed within a first backside metallization layer under the first S/D structure and the second S/D structure, and the third backside conductive structure is disposed within a second backside metallization layer under the first backside metallization layer.

Clause 3. The semiconductor structure of clause 2, further comprising: a fourth backside conductive structure within the second backside metallization layer; and a metallization structure disposed within a third backside metallization layer under the second backside metallization layer, the fourth backside conductive structure connecting the metallization structure to another backside conductive structure in the first backside metallization layer.

Clause 4. The semiconductor structure of clause 1, wherein: the first backside conductive structure and the second backside conductive structure are disposed within a first backside metallization layer under the first S/D structure and the second S/D structure, and the third backside conductive structure is disposed within a lower portion of the first backside metallization layer.

Clause 5. The semiconductor structure of clause 4, further comprising: a fourth backside conductive structure within a second backside metallization layer under the first backside metallization layer; and a metallization structure disposed within a third backside metallization layer under the second backside metallization layer, the fourth backside conductive structure connecting the metallization structure to another backside conductive structure in the first backside metallization layer.

Clause 6. The semiconductor structure of any of clauses 1 to 5, further comprising: a dielectric structure under a connecting portion of the gate stack between the first gate structure and the second gate structure, wherein: the third backside conductive structure is disposed at least partially under the connecting portion of the gate stack, the dielectric structure being configured to electrically isolate the third backside conductive structure from a bottom gate electrode portion of the connecting portion of the gate stack.

Clause 7. The semiconductor structure of clause 6, wherein: the dielectric structure is in contact with the bottom gate electrode portion of the connecting portion of the gate stack.

Clause 8. The semiconductor structure of clause 7, wherein: at least a portion of the third backside conductive structure is above a lower surface of the gate stack and extends along an inner spacer of the connecting portion of the gate stack.

Clause 9. The semiconductor structure of clause 6 or clause 7, wherein: an entirety of the third backside conductive structure is below the connecting portion of the gate stack.

Clause 10. The semiconductor structure of clause 6, clause 7, or clause 9, wherein: the dielectric structure comprises an etch stop layer under the connecting portion of the gate stack.

Clause 11. A method of manufacturing a semiconductor structure, comprising: forming a gate stack extending along a first direction in a front portion of the semiconductor structure, the gate stack including a first gate structure and a second gate structure, the second gate structure being offset from the first gate structure in the first direction, a first S/D structure being disposed adjacent the first gate structure, a second S/D structure being disposed adjacent the second gate structure, and the first S/D structure and the second S/D structure being offset from each other in a second direction; forming a first backside conductive structure in contact with the first S/D structure and disposed at least partially in a back portion of the semiconductor structure opposing the front portion; forming a second backside conductive structure in contact with the second S/D structure and disposed at least partially in the back portion of the semiconductor structure; and forming a third backside conductive structure disposed in the back portion of the semiconductor structure, the third backside conductive structure extending along the second direction and in contact with the first backside conductive structure and the second backside conductive structure.

Clause 12. The method of clause 11, wherein: the first backside conductive structure and the second backside conductive structure are formed within a first backside metallization layer under the first S/D structure and the second S/D structure, and the third backside conductive structure is formed within a second backside metallization layer under the first backside metallization layer.

Clause 13. The method of clause 12, further comprising: forming a fourth backside conductive structure within the second backside metallization layer; and forming a metallization structure disposed within a third backside metallization layer under the second backside metallization layer, the fourth backside conductive structure connecting the metallization structure to another backside conductive structure in the first backside metallization layer.

Clause 14. The method of clause 11, wherein: the first backside conductive structure and the second backside conductive structure are formed within a first backside metallization layer under the first S/D structure and the second S/D structure, and the third backside conductive structure is formed within a lower portion of the first backside metallization layer.

Clause 15. The method of clause 14, further comprising: forming a fourth backside conductive structure within a second backside metallization layer under the first backside metallization layer; and forming a metallization structure within a third backside metallization layer under the second backside metallization layer, the fourth backside conductive structure connecting the metallization structure to another backside conductive structure in the first backside metallization layer.

Clause 16. The method of any of clauses 11 to 15, further comprising: forming a dielectric structure under a connecting portion of the gate stack between the first gate structure and the second gate structure, wherein: the third backside conductive structure is formed at least partially under the connecting portion of the gate stack, the dielectric structure being configured to electrically isolate the third backside conductive structure from a bottom gate electrode portion of the connecting portion of the gate stack.

Clause 17. The method of clause 16, wherein the forming the dielectric structure comprises: removing a portion of a gate dielectric portion of the connecting portion of the gate stack to expose the bottom gate electrode portion of the connecting portion of the gate stack; and performing an area selective deposition process to form the dielectric structure.

Clause 18. The method of clause 17, wherein the forming the third backside conductive structure comprises: removing a portion of a front side interlayer dielectric layer adjacent an inner spacer of the connecting portion of the gate stack to define an opening, wherein the third backside conductive structure is formed in the opening such that at least a portion of the third backside conductive structure is above a lower surface of the gate stack and extends along the inner spacer of the connecting portion of the gate stack.

Clause 19. The method of clause 17, wherein: an entirety of the third backside conductive structure is below the connecting portion of the gate stack.

Clause 20. The method of clause 16, further comprising: forming an etch stop layer as the dielectric structure under the connecting portion of the gate stack.

Clause 21. An electronic device, comprising: an integrated circuit device including a semiconductor structure, and the semiconductor structure comprising: a gate stack extending along a first direction in a front portion of the semiconductor structure, the gate stack including a first gate structure and a second gate structure offset from each other in the first direction; a first source/drain (S/D) structure adjacent the first gate structure; a second S/D structure adjacent the second gate structure, the second S/D structure being offset from the first S/D structure in a second direction; a first backside conductive structure in contact with the first S/D structure and disposed at least partially in a back portion of the semiconductor structure opposing the front portion; a second backside conductive structure in contact with the second S/D structure and disposed at least partially in the back portion of the semiconductor structure; and a third backside conductive structure disposed in the back portion of the semiconductor structure, the third backside conductive structure extending along the second direction and in contact with the first backside conductive structure and the second backside conductive structure.

Clause 22. The electronic device of clause 21, wherein: the first backside conductive structure and the second backside conductive structure are disposed within a first backside metallization layer under the first S/D structure and the second S/D structure, and the third backside conductive structure is disposed within a second backside metallization layer under the first backside metallization layer.

Clause 23. The electronic device of clause 22, wherein the semiconductor structure further comprises: a fourth backside conductive structure within the second backside metallization layer; and a metallization structure disposed within a third backside metallization layer under the second backside metallization layer, the fourth backside conductive structure connecting the metallization structure to another backside conductive structure in the first backside metallization layer.

Clause 24. The electronic device of clause 21, wherein: the first backside conductive structure and the second backside conductive structure are disposed within a first backside metallization layer under the first S/D structure and the second S/D structure, and the third backside conductive structure is disposed within a lower portion of the first backside metallization layer.

Clause 25. The electronic device of clause 24, wherein the semiconductor structure further comprises: a fourth backside conductive structure within a second backside metallization layer under the first backside metallization layer; and a metallization structure disposed within a third backside metallization layer under the second backside metallization layer, the fourth backside conductive structure connecting the metallization structure to another backside conductive structure in the first backside metallization layer.

Clause 26. The electronic device of any of clauses 21 to 25, wherein the semiconductor structure further comprises: a dielectric structure under a connecting portion of the gate stack between the first gate structure and the second gate structure, wherein the third backside conductive structure is disposed at least partially under the connecting portion of the gate stack, the dielectric structure being configured to electrically isolate the third backside conductive structure from a bottom gate electrode portion of the connecting portion of the gate stack.

Clause 27. The electronic device of clause 26, wherein: the dielectric structure is in contact with the bottom gate electrode portion of the connecting portion of the gate stack.

Clause 28. The electronic device of clause 27, wherein: at least a portion of the third backside conductive structure is above a lower surface of the gate stack and extends along an inner spacer of the connecting portion of the gate stack.

Clause 29. The electronic device of clause 26 or clause 27, wherein: an entirety of the third backside conductive structure is below the connecting portion of the gate stack.

Clause 30. The electronic device of clause 26, clause 27, or clause 29, wherein: the dielectric structure comprises an etch stop layer under the connecting portion of the gate stack.

Clause 31. The electronic device of any of clauses 21 to 30, wherein the electronic device comprises a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Nothing stated or illustrated depicted in this application is intended to dedicate any component, action, feature, benefit, advantage, or equivalent to the public, regardless of whether the component, action, feature, benefit, advantage, or the equivalent is recited in the claims.

It should furthermore be noted that methods, systems, and apparatus disclosed in the description or in the claims can be implemented by a device comprising means for performing the respective actions and/or functionalities of the methods disclosed. Furthermore, While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order.

Further, no component, function, action, or instruction described or claimed herein should be construed as critical or essential unless explicitly described as such. Furthermore, as used herein, the terms “set,” “group,” and the like are intended to include one or more items and may be used interchangeably with “at least one,” “one or more,” and the like. Also, as used herein, the terms “has,” “have,” “having,” and the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more items and may be used interchangeably with “at least one,” “one or more,” and the like. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination. In some examples, an individual action can be subdivided into one or more sub-actions or contain one or more sub-actions. Such sub-actions can be contained in the disclosure of the individual action and be part of the disclosure of the individual action.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A semiconductor structure, comprising:
a gate stack extending along a first direction in a front portion of the semiconductor structure, the gate stack including a first gate structure and a second gate structure offset from each other in the first direction;
a first source/drain (S/D) structure adjacent the first gate structure;
a second S/D structure adjacent the second gate structure, the second S/D structure being offset from the first S/D structure in a second direction;
a first backside conductive structure in contact with the first S/D structure and disposed at least partially in a back portion of the semiconductor structure opposing the front portion;
a second backside conductive structure in contact with the second S/D structure and disposed at least partially in the back portion of the semiconductor structure; and
a third backside conductive structure disposed in the back portion of the semiconductor structure, the third backside conductive structure extending along the second direction and in contact with the first backside conductive structure and the second backside conductive structure.

2. The semiconductor structure of claim 1, wherein:
the first backside conductive structure and the second backside conductive structure are disposed within a first backside metallization layer under the first S/D structure and the second S/D structure, and
the third backside conductive structure is disposed within a second backside metallization layer under the first backside metallization layer.

3. The semiconductor structure of claim 2, further comprising:
a fourth backside conductive structure within the second backside metallization layer; and
a metallization structure disposed within a third backside metallization layer under the second backside metallization layer, the fourth backside conductive structure connecting the metallization structure to another backside conductive structure in the first backside metallization layer.

4. The semiconductor structure of claim 1, wherein:
the first backside conductive structure and the second backside conductive structure are disposed within a first backside metallization layer under the first S/D structure and the second S/D structure, and
the third backside conductive structure is disposed within a lower portion of the first backside metallization layer.

5. The semiconductor structure of claim 4, further comprising:
a fourth backside conductive structure within a second backside metallization layer under the first backside metallization layer; and
a metallization structure disposed within a third backside metallization layer under the second backside metallization layer, the fourth backside conductive structure connecting the metallization structure to another backside conductive structure in the first backside metallization layer.

6. The semiconductor structure of claim 1, further comprising:
a dielectric structure under a connecting portion of the gate stack between the first gate structure and the second gate structure,
wherein:
the third backside conductive structure is disposed at least partially under the connecting portion of the gate stack, the dielectric structure being configured to electrically isolate the third backside conductive structure from a bottom gate electrode portion of the connecting portion of the gate stack.

7. The semiconductor structure of claim 6, wherein:
the dielectric structure is in contact with the bottom gate electrode portion of the connecting portion of the gate stack.

8. The semiconductor structure of claim 7, wherein:
at least a portion of the third backside conductive structure is above a lower surface of the gate stack and extends along an inner spacer of the connecting portion of the gate stack.

9. The semiconductor structure of claim 6, wherein:
an entirety of the third backside conductive structure is below the connecting portion of the gate stack.

10. The semiconductor structure of claim 6, wherein:
the dielectric structure comprises an etch stop layer under the connecting portion of the gate stack.

11. A method of manufacturing a semiconductor structure, comprising:
forming a gate stack extending along a first direction in a front portion of the semiconductor structure, the gate stack including a first gate structure and a second gate structure, the second gate structure being offset from the first gate structure in the first direction, a first S/D structure being disposed adjacent the first gate structure, a second S/D structure being disposed adjacent the second gate structure, and the first S/D structure and the second S/D structure being offset from each other in a second direction;
forming a first backside conductive structure in contact with the first S/D structure and disposed at least partially in a back portion of the semiconductor structure opposing the front portion;
forming a second backside conductive structure in contact with the second S/D structure and disposed at least partially in the back portion of the semiconductor structure; and
forming a third backside conductive structure disposed in the back portion of the semiconductor structure, the third backside conductive structure extending along the second direction and in contact with the first backside conductive structure and the second backside conductive structure.

12. The method of claim 11, wherein:
the first backside conductive structure and the second backside conductive structure are formed within a first backside metallization layer under the first S/D structure and the second S/D structure, and
the third backside conductive structure is formed within a second backside metallization layer under the first backside metallization layer.

13. The method of claim 12, further comprising:
forming a fourth backside conductive structure within the second backside metallization layer; and
forming a metallization structure disposed within a third backside metallization layer under the second backside metallization layer, the fourth backside conductive structure connecting the metallization structure to another backside conductive structure in the first backside metallization layer.

14. The method of claim 11, wherein:
the first backside conductive structure and the second backside conductive structure are formed within a first backside metallization layer under the first S/D structure and the second S/D structure, and
the third backside conductive structure is formed within a lower portion of the first backside metallization layer.

15. The method of claim 14, further comprising:
forming a fourth backside conductive structure within a second backside metallization layer under the first backside metallization layer; and
forming a metallization structure within a third backside metallization layer under the second backside metallization layer, the fourth backside conductive structure connecting the metallization structure to another backside conductive structure in the first backside metallization layer.

16. The method of claim 11, further comprising:
forming a dielectric structure under a connecting portion of the gate stack between the first gate structure and the second gate structure,
wherein:
the third backside conductive structure is formed at least partially under the connecting portion of the gate stack, the dielectric structure being configured to electrically isolate the third backside conductive structure from a bottom gate electrode portion of the connecting portion of the gate stack.

17. The method of claim 16, wherein the forming the dielectric structure comprises:
removing a portion of a gate dielectric portion of the connecting portion of the gate stack to expose the bottom gate electrode portion of the connecting portion of the gate stack; and
performing an area selective deposition process to form the dielectric structure.

18. The method of claim 17, wherein the forming the third backside conductive structure comprises:
removing a portion of a front side interlayer dielectric layer adjacent an inner spacer of the connecting portion of the gate stack to define an opening,
wherein the third backside conductive structure is formed in the opening such that at least a portion of the third backside conductive structure is above a lower surface of the gate stack and extends along the inner spacer of the connecting portion of the gate stack.

19. The method of claim 17, wherein:
an entirety of the third backside conductive structure is below the connecting portion of the gate stack.

20. The method of claim 16, further comprising:
forming an etch stop layer as the dielectric structure under the connecting portion of the gate stack.

21. An electronic device, comprising:
an integrated circuit device including a semiconductor structure, and the semiconductor structure comprising:
a gate stack extending along a first direction in a front portion of the semiconductor structure, the gate stack including a first gate structure and a second gate structure offset from each other in the first direction;
a first source/drain (S/D) structure adjacent the first gate structure;
a second S/D structure adjacent the second gate structure, the second S/D structure being offset from the first S/D structure in a second direction;
a first backside conductive structure in contact with the first S/D structure and disposed at least partially in a back portion of the semiconductor structure opposing the front portion;
a second backside conductive structure in contact with the second S/D structure and disposed at least partially in the back portion of the semiconductor structure; and
a third backside conductive structure disposed in the back portion of the semiconductor structure, the third backside conductive structure extending along the second direction and in contact with the first backside conductive structure and the second backside conductive structure.

22. The electronic device of claim 21, wherein:
the first backside conductive structure and the second backside conductive structure are disposed within a first backside metallization layer under the first S/D structure and the second S/D structure, and
the third backside conductive structure is disposed within a second backside metallization layer under the first backside metallization layer.

23. The electronic device of claim 22, wherein the semiconductor structure further comprises:
a fourth backside conductive structure within the second backside metallization layer; and
a metallization structure disposed within a third backside metallization layer under the second backside metallization layer, the fourth backside conductive structure connecting the metallization structure to another backside conductive structure in the first backside metallization layer.

24. The electronic device of claim 21, wherein:
the first backside conductive structure and the second backside conductive structure are disposed within a first backside metallization layer under the first S/D structure and the second S/D structure, and
the third backside conductive structure is disposed within a lower portion of the first backside metallization layer.

25. The electronic device of claim 24, wherein the semiconductor structure further comprises:
a fourth backside conductive structure within a second backside metallization layer under the first backside metallization layer; and
a metallization structure disposed within a third backside metallization layer under the second backside metallization layer, the fourth backside conductive structure connecting the metallization structure to another backside conductive structure in the first backside metallization layer.

26. The electronic device of claim 21, wherein the semiconductor structure further comprises:
a dielectric structure under a connecting portion of the gate stack between the first gate structure and the second gate structure,
wherein the third backside conductive structure is disposed at least partially under the connecting portion of the gate stack, the dielectric structure being configured to electrically isolate the third backside conductive structure from a bottom gate electrode portion of the connecting portion of the gate stack.

27. The electronic device of claim 26, wherein:
the dielectric structure is in contact with the bottom gate electrode portion of the connecting portion of the gate stack.

28. The electronic device of claim 27, wherein:
at least a portion of the third backside conductive structure is above a lower surface of the gate stack and extends along an inner spacer of the connecting portion of the gate stack.

29. The electronic device of claim 26, wherein:
an entirety of the third backside conductive structure is below the connecting portion of the gate stack.

30. The electronic device of claim 26, wherein:
the dielectric structure comprises an etch stop layer under the connecting portion of the gate stack.

31. The electronic device of claim 21, wherein the electronic device comprises a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
